(19) United States
(12) Patent Application Publication
(10) Pub. No.: US 2022/0283351 A1
(43) Pub. Date: Sep. 8, 2022

(54) LAMINATE, OPTICAL DEVICE, AND DISPLAY DEVICE

(71) Applicant: FUJIFILM Corporation, Tokyo (JP)

(72) Inventors: Naoya SHIBATA, Kanagawa (JP); Yasukazu KUWAYAMA, Kanagawa (JP); Naoki KOITO, Kanagawa (JP); Yumi KATO, Kanagawa (JP); Fumitake MITOBE, Kanagawa (JP); Naoyoshi YAMADA, Kanagawa (JP)

(73) Assignee: FUJIFILM Corporation, Tokyo (JP)

(21) Appl. No.: 17/752,409

(22) Filed: May 24, 2022

Related U.S. Application Data
(63) Continuation of application No. PCT/JP2020/042748, filed on Nov. 17, 2020.

(30) Foreign Application Priority Data
Dec. 2, 2019 (JP) 2019-218273
Dec. 26, 2019 (JP) 2019-236920
May 27, 2020 (JP) 2020-092501
Sep. 7, 2020 (JP) 2020-149976
Oct. 16, 2020 (JP) 2020-174814

(51) Int. Cl. G02B 5/30; C09J 133/10

(52) U.S. Cl. CPC G02B 5/3016; C09J 133/10

(57) ABSTRACT

An object of the present invention is to provide a laminate including a light absorption anisotropic layer, in which a decrease in a degree of polarization is suppressed even in a case where the laminate is simultaneously stretched in a plurality of directions, and an optical device and a display device, each using the laminate. The laminate of an embodiment of the present invention is a laminate having at least a resin substrate and a light absorption anisotropic layer, in which a tan δ peak temperature of the resin substrate is 170° C. or lower, the light absorption anisotropic layer includes a liquid crystalline compound and a dichroic substance, and an alignment degree of the dichroic substance is 0.95 or more.

### CROSS-REFERENCE TO RELATED APPLICATIONS

This application is a Continuation of PCT International Application No. PCT/JP2020/042748 filed on Nov. 17, 2020, which claims priority under 35 U.S.C. § 119(a) to Japanese Patent Application No. 2019-218273 filed on Dec. 2, 2019, Japanese Patent Application No. 2019-236920 filed on Dec. 26, 2019, Japanese Patent Application No. 2020-092501 filed on May 27, 2020, Japanese Patent Application No. 2020-149976 filed on Sep. 7, 2020 and Japanese Patent Application No. 2020-174814 filed on Oct. 16, 2020. Each of the above applications is hereby expressly incorporated by reference, in its entirety, into the present application.

### BACKGROUND OF THE INVENTION

### 1. Field of the Invention

The present invention relates to a laminate, an optical device, and a display device.

### 2. Description of the Related Art

A polarizer is used in various optical devices from the viewpoint of antireflection, suppression of stray light, and the like, but each of members used in the polarizer is required to have a degree of freedom in a shape such as a curved surface due to an improvement in designability and ease of designing.

In the related art, an iodine polarizer has often been used in a polarizer. The iodine polarizer has been manufactured by dissolving iodine, adsorbing the iodine onto a film of a high-molecular-weight material such as polyvinyl alcohol (PVA), and stretching the film at a high magnification in one direction, and it has been difficult to sufficiently reduce a thickness of the film. In addition, as described in JP2019-194685A, a stretched PVA had a tendency to have a change in the shape over time, and it was thus hard to use in a curved surface shape.

In recent years, with regard to the iodine polarizer, a polarizing element in which a liquid crystalline compound or a dichroic azo coloring agent is applied onto a substrate such as a transparent film, and the dichroic azo coloring agent is aligned using an intermolecular interaction and the like has been investigated. For example, JP2019-194685A describes, as a polarizer used in a polarizing plate having a curved part, a polarizer having a first surface and a second surface, and having a thickness of 15 μm or less ([Claim 1]), and further describes, as such the polarizer, a polarizer including a polarizing layer including a cured product of a liquid crystal compound and a dichroic coloring agent, in which the dichroic coloring agent is dispersed and aligned ([Claim 4]).

### SUMMARY OF THE INVENTION

However, it is necessary to mold a polarizing film into a shape along a curved surface in order to use a polarizer using liquid crystal alignment for the curved surface of an in-vehicle display, a lens, or the like. In addition, in a case where such molding is carried out, a tensile stress in a plurality of directions is generated.

The present inventors have clarified that stretching in the direction of an alignment axis does not reduce a degree of polarization, whereas stretching in a direction different from the direction of the alignment axis reduces the degree of polarization, and that simultaneous stretching in biaxial directions disturbs the alignment and thus, the degree of polarization is more greatly decreased.

Therefore, an object of the present invention is to provide a laminate including a light absorption anisotropic layer, in which a decrease in a degree of polarization is suppressed even in a case where the laminate is simultaneously stretched in a direction different from the direction of the alignment axis or stretched in a plurality of directions, and an optical device and a display device, each using the laminate.

The present inventors have conducted intensive studies in order to accomplish the object, and as a result, they have found that in a ease where a laminate having a specific resin substrate and a light absorption anisotropic layer having a predetermined value or more of an alignment degree of a dichroic substance is used, it is possible to realize an absorbent polarizing film in which a decrease in a degree of polarization is suppressed even in a case where the film is simultaneously stretched in a plurality of directions, thereby completing the present invention.

That is, the present inventors have found that the object can be accomplished by the following configurations.

[1] A laminate comprising at least:

a resin substrate; and

a light absorption anisotropic layer,

in which a tan δ peak temperature of the resin substrate is 170° C. or lower,

the light absorption anisotropic layer includes a liquid crystalline compound and a dichroic substance, and

an alignment degree of the dichroic substance is 0.95 or more.

[2] The laminate as described in [1],

in which the tan δ peak temperature of the resin substrate is 130° C. or lower.

[3] The laminate as described in [1] or [2],

in which a storage elastic modulus of the resin substrate at the tan δ peak temperature is 100 kPa or less.

[4] The laminate as described in any one of [1] to [3],

in which the resin substrate, an adhesive layer, and the light absorption anisotropic layer are arranged in this order.

[5] The laminate as described in [4],

in which the adhesive layer is an ultraviolet curable adhesive layer.

[6] The laminate as described in [5],

in which the adhesive layer is an adhesive layer including at least a (meth)acrylate compound.

[7] The laminate as described in any one of [1] to [6], further comprising an alignment layer.

[8] The laminate as described in [7],

in which the alignment layer is a layer formed from a composition containing a radically polymerizable compound.

[9] The laminate as described in any one of [1] to [8],

in which the resin substrate, an adhesive layer, the light absorption anisotropic layer, and an alignment layer are arranged in this order.

[10] The laminate as described in [9],

in which the adhesive layer is an ultraviolet curable adhesive layer.

[11] The laminate as described in [10],

in which the adhesive layer is an adhesive layer including at least a (meth)acrylate compound.

[12] The laminate as described in any one of [1] to [11],

in which the light absorption anisotropic layer is formed from a composition having a high-molecular-weight liquid crystalline compound.

[13] The laminate as described in any one of [1] to [12],

in which a molar content of a radically polymerizable group is 0.6 mmol/g or more with respect to a solid content weight of a composition forming the light absorption anisotropic layer.

[14] The laminate as described in any one of [1] to [13],

in which the laminate has a curved surface.

[15] An optical device having a curved surface,

in which the laminate as described in [14] is arranged along the curved surface.

[16] A display device comprising a plurality of members having a curved surface,

in which the laminate as described in [14] is arranged along a further visible side of a curved surface of a member present on the most visible side among the members having the curved surface.

According to the present invention; it is possible to provide a laminate in which a decrease in a degree of polarization is suppressed even in a case where the laminate is simultaneously stretched in a direction different from a direction of the alignment axis or stretched in a plurality of directions, and an optical device or a display device, each using the laminate.

### BRIEF DESCRIPTION OF THE DRAWINGS

FIG. 1 is a schematic cross-sectional view showing an example of a laminate of an embodiment of the present invention.

FIG. 2 is a schematic cross-sectional view showing an example of the laminate of the embodiment of the present invention.

FIG. 3 is a cross-sectional side view of a head-mounted display which is an example of a display device of an embodiment of the present invention.

FIG. 4 is a cross-sectional side view of a head-mounted display which is an example of the display device of the embodiment of the present invention.

FIG. 5 is a schematic view showing an alignment of a laminate of an embodiment of the present invention.

### DESCRIPTION OF THE PREFERRED EMBODIMENTS

Hereinafter, the present invention will be described in detail.

Description of configuration requirements described below may be made based on representative embodiments of the present invention, but the present invention is not limited to such embodiments.

Furthermore, in the present specification, a numerical range expressed using “to” means a range which includes the preceding and succeeding numerical values of “to” as a lower limit value and an upper limit value, respectively.

In addition, in the present specification, being parallel, being orthogonal, being horizontal, and being perpendicular do not mean being parallel, being orthogonal, being horizontal, and being perpendicular in strict meanings, respectively, but mean a range of being parallel ±10°, a range of being orthogonal ±10°, a range of being horizontal ±10°, and a range of being perpendicular ±10°, respectively.

Moreover, in the present specification, as each component, a substance corresponding to each component may be used alone or in combination of two or more kinds thereof. Here, in a case where two or more kinds of substances are used in combination for each component, a content of the component refers to a total content of the substances used in combination unless otherwise specified.

Moreover, in the present specification, “(meth)acrylate” is a notation representing “acrylate” or “methacrylate”, “(meth)acryl” is a notation representing “acryl” or “methacryl”, and “(meth)acryloyl” is a notation representing “acryloyl” or “methacryloyl”.

[Laminate]

The laminate of the embodiment of the present invention is a laminate having a resin substrate and a light absorption anisotropic layer, in which a tan δ of the resin substrate is 170° C. or lower, the light absorption anisotropic layer includes a liquid crystalline compound and a dichroic substance, and an alignment degree of the dichroic substance is 0.95 or more.

The alignment degree of the dichroic substance in the light absorption anisotropic layer is more preferably 0.97 or more. The higher the alignment degree, the smaller a change in the degree of polarization in a case where the laminate is stretched in a plurality of directions at the same time.

In the present invention, by setting a tan δ peak temperature of the resin substrate to 170° C. or lower and allowing the dichroic substance in the light absorption anisotropic layer to have a high alignment degree of 0.95 or more as described above, it is possible to suppress a decrease in the degree of polarization even in a case where the laminate is stretched in a direction different from the direction of the alignment axis or simultaneously stretched in a plurality of directions.

Details of a reason thereof have not been clarified yet, but the present inventors have speculated that the reason is to be as follows.

First, it can be presumed that by setting the tan δ peak temperature of the resin substrate of the optical laminate of the embodiment of the present invention to 170° C. or lower, the stretching is performed in a temperature region that does not affect the alignment state of the liquid crystalline compound in the light absorption anisotropic layer, a curved surface shape can be imparted in the temperature region.

In addition, the light absorption anisotropic layer of the optical laminate of the embodiment of the present invention has a dichroic substance, and is arranged in various directions at a molecular level. In a case where the directions of these individual molecules are averaged, they converge in one direction, which is an alignment axis of the dichroic substance (see FIG. 5). A case where a stretching stress perpendicular to the alignment axis acts is considered. It is presumed that molecules arranged in a direction parallel to the alignment axis do not change to a direction even in a case where the stretching stress is applied. On the other hand, it can be presumed that molecules deviated from a direction parallel to the alignment axis change in a direction in which the deviation further increases with respect to the alignment axis due to the stretching stress.

Here, in the light absorption anisotropic layer having a high alignment degree, it is considered that since most of the molecules are arranged in the alignment axis direction, an influence thereof is small even in a case where a stretching stress perpendicular to the alignment axis acts, and as a result, a change in the degree of polarization is also small.

Hereinafter, each component included in the laminate will be described in detail.

[Resin Substrate]

The resin substrate used in the present invention has tan δ peak temperature of 170° C. or lower.

In addition, from the viewpoint of enabling a thermal deformation treatment at a low temperature, the resin substrate preferably has tan δ peak temperature of 150° C. or lower, and more preferably has tan δ peak temperature of 130° C. or lower.

Here, a method for measuring the tan δ will be described.

Using a dynamic viscoelasticity measuring device (DVA-200 manufactured by IT Measurement Control Co., Ltd.), E″ (loss elastic modulus) and E′ (storage elastic modulus) were measured in advance for a film sample which had been humidity-controlled for 2 hours or more in an atmosphere at a temperature of 25° C. and a humidity of 60% Rh, thereby obtain tan δ (=E″/E′) as a value as determined.

Device: DVA-200 manufactured by IT Measurement Control Co., Ltd.

Sample: 5 mm, length 50 mm (gap 20 mm)

Measurement conditions: Tension mode

Measurement temperature: −150° C. to 220° C.

Heating conditions: 5° C./min

Frequency: 1 Hz

Furthermore, in general, in optical applications, a stretched resin substrate is often used and a tan δ peak temperature thereof often changes by a stretching treatment. For example, in a triacetyl cellulose (TAC) substrate (TG40, manufactured by Fujifilm Corporation), the tan δ peak temperature is 180° C. or higher.

As the resin substrate used in the present invention, various optical resins can be used without limitation as long as the tan δ peak temperature is 170° C. or lower. Examples of the optical resin include plastics including, for example, polyolefins such as polyethylene, polypropylene, and a norbornene-based polymer; cyclic olefin-based resins; polyvinyl alcohol; polyethylene terephthalate; polymethacrylic acid esters; and polyacrylic acid esters; polyethylene naphthalate; polycarbonate; polysulfone; polyether sulfone; polyether ketone; and polyphenylene sulfide and polyphenylene oxide.

Among those, the cyclic olefin resin, the acrylic resin, or the polycarbonate is preferable, the acrylic resin is more preferable, and the polymethacrylic acid ester is still more preferable, from the viewpoint that it is easily available from the market and has excellent transparency.

Examples of the commercially available resin substrates include TECHNOLLOY S001G, TECHNOLLOY S014G, TECHNOLLOY S000, TECHNOLLOY C001, and TECHNOLLOY C000 (Sumika Acryl Co., Ltd.), LUMIRROR U type, LUMIRROR FX10, and LUMIRROR SF20 (Toray industries, Inc.), HK-53A (Higashiyama Film Co., Ltd.), TEFLEX FT3 (Teijin DuPont Films Limited), ESCENA″ and SCA40 Sekisui Chemical Co., Ltd.), ZEONOR Film (Optes Co., Ltd.), and ARTON Film (JSR Co., Ltd.).

The resin substrate used in the present invention preferably has a storage elastic modulus of 500 kPa or less, more preferably has a storage elastic modulus of 100 kPa or less, and still more preferably has a storage elastic modulus of 50 kPa or less at a tan δ peak temperature since it makes the stretching treatment easier.

Here, the storage elastic modulus at a tan δ peak temperature refers to a storage elastic modulus at a tan δ peak temperature among values of E′ (storage elastic modulus) measured by the above-mentioned method for measuring the tan δ.

A thickness of the resin substrate is not particularly limited, but is preferably 5 to 300 μm, more preferably 5 to 100 μm, and still more preferably 5 to 30 μm.

[Light Absorption Anisotropic Layer]

The light absorption anisotropic layer used in the present invention contains a liquid crystalline compound and a dichroic substance, and an alignment degree of the dichroic substance is 0.95 or more.

Such a light absorption anisotropic layer is preferably formed using a composition containing a liquid crystalline compound and a dichroic substance (the composition is hereinafter simply referred to as a “composition for forming a light absorption anisotropic layer”).

In particular, it is preferable that the liquid crystal compound or the dichroic coloring agent included in the composition for forming a light absorption anisotropic layer has a radically polymerizable group from the viewpoint that a decrease in the degree of polarization during heating is suppressed.

A molar content ratio of the radically polymerizable group is preferably 0.6 mmol/g or more, more preferably 1.0 mmol/g or more, and still more preferably 1.5 mmol/g or more with respect to the solid content weight of the composition for forming a light absorption anisotropic layer.

<Liquid Crystalline Compound>

The composition for forming a light absorption anisotropic layer contains a liquid crystalline compound.

The liquid crystalline compound is preferably a liquid crystalline compound which does not exhibit dichroism in the visible region.

As the liquid crystalline compound, both of a low-molecular-weight liquid crystalline compound and a high-molecular-weight liquid crystalline compound can be used. Here, the “low-molecular-weight liquid crystalline compound” refers to a liquid crystalline compound having no repeating unit in the chemical structure. In addition, the “high-molecular-weight liquid crystalline compound” refers to a liquid crystalline compound having a repeating unit in the chemical structure.

Examples of the low-molecular-weight liquid crystalline compound include the liquid crystalline compounds described in paragraphs [0027] to [0034] of JP2013-228706A. Among these, the low-molecular-weight liquid crystalline compound exhibiting a smectic property is preferable.

Examples of the high-molecular-weight liquid crystalline compound include the thermotropic liquid crystalline polymers described in JP2011-237513A. In addition, the high-molecular-weight liquid crystalline compound preferably has a crosslinkable group (for example, an acryloyl group and a methacryloyl group) at a terminal.

The liquid crystalline compound may be used alone or in combination of two or more kinds thereof. It is also preferable to use a high-molecular-weight liquid crystalline compound and a low-molecular-weight liquid crystalline compound in combination.

A content of the liquid crystalline compound is preferably 25 to 2,000 parts by mass, more preferably 33 to 1,000 parts by mass, and still more preferably 50 to 500 parts by mass with respect to 100 parts by mass of a content of the dichroic substance in the composition for forming a light absorption anisotropic layer. By setting the content of the liquid crystalline compound to be in the range, the alignment degree of the polarizer is further improved.

For a reason that the alignment degree of a light absorption anisotropic layer thus obtained is further increased, the liquid crystalline compound is preferably a high-molecular-weight liquid crystalline compound, and more preferably a high-molecular-weight liquid crystalline compound including a repeating unit represented by Formula (1) (hereinafter also simply referred to as a “repeating unit (1)”).

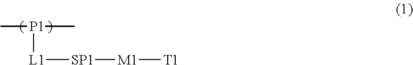

In Formula (1), P1 represents a main chain of the repeating unit, L1 represents a single bond or a divalent linking group, SP1 represents a spacer group, M1 represents a mesogenic group, and T1 represents a terminal group.

Specific examples of the main chain of the repeating unit represented by P1 include groups represented by Formulae (P1-A) to (P1-D), and among these, the group represented by Formula (P1-A) is preferable from the viewpoints of a diversity of monomers used as raw materials and easy handling.

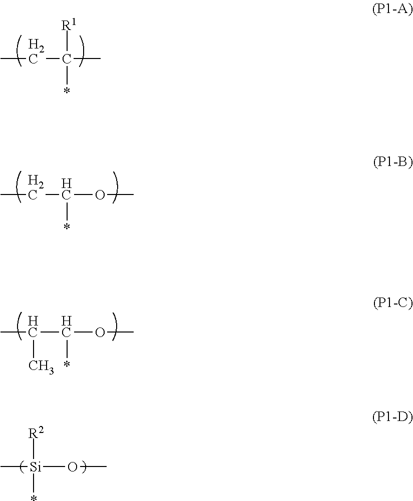

In Formulae (P1-A) to (P1-D), “*” represents a bonding position to L1 in Formula (1). In Formula (P1-A), R¹ represents a hydrogen atom or a methyl group. In Formula (P1-D), R² represents an alkyl group.

For a reason that the alignment degree of a light absorption anisotropic layer thus obtained is further increased, it is preferable that the group represented by Formula (P1-A) is one unit of a partial structure of poly(meth)acrylic acid ester obtained by polymerization of (meth)acrylic acid ester.

For a reason that the alignment degree of a light absorption anisotropic layer thus obtained is further increased, it is preferable that the group represented by Formula (P1-B) is an ethylene glycol unit in polyethylene glycol obtained by polymerizing ethylene glycol.

For a reason that the alignment degree of a light absorption anisotropic layer thus obtained is further increased, it is preferable that the group represented by Formula (P1-C) is a propylene glycol unit obtained by polymerizing propylene glycol.

For a reason that the alignment degree of a light absorption anisotropic layer thus obtained is further increased, it is preferable that the group represented by Formula (P1-D) is a siloxane unit of a polysiloxane obtained by polycondensation of silanol.

L1 is a single bond or a divalent linking group.

Examples of the divalent linking group represented by L1 include —C(O)O—, —OC(O)—, —O—, —S—, —C(O)NR³—, —NR³C(O)—, —SO₂—, and —NR³R⁴—. In the formulae, R³ and R⁴ each independently represent a hydrogen atom, or an alkyl group having 1 to 6 carbon atoms, which may have a substituent.

In a case where P1 is the group represented by Formula (P1-A), it is preferable that L1 is a group represented by —C(O)O— for a reason that the alignment degree of a light absorption anisotropic layer thus obtained is further increased.

In a case where P1 is the group represented by each of Formulae (P1-B) to (P1-D), it is preferable that L1 is the single bond for a reason that the alignment degree of a light absorption anisotropic layer thus obtained is further increased.

For reasons of easy exhibition of liquid crystallinity, availability of a raw material, and the like, it is preferable that the spacer group represented by SP1 includes at least one structure selected from the group consisting of an oxyethylene structure, an oxypropylene structure, a polysiloxane structure, and an alkylene fluoride structure.

Here, the oxyethylene structure represented by SP1 is preferably a group represented by *—(CH₂—CH₂O)ₙ₁—*. In the formula, n1 represents an integer of 1 to 20, and * represents a bonding position to L1 or M1 in Formula (1). For a reason that the alignment degree of a light absorption anisotropic layer thus obtained is further increased, n1 is preferably an integer of 2 to 10, more preferably an integer of 2 to 4, and most preferably 3.

In addition, for a reason that the alignment degree of a light absorption anisotropic layer thus obtained is further increased, it is preferable that the oxypropylene structure represented by SP1 is a group represented by *—(CH(CH₃)—CH₂O)ₙ₂—*. In the formula, n2 represents an integer of 1 to 3, and * represents a bonding position to L1 or M1.

In addition, for a reason that the alignment degree of a light absorption anisotropic layer thus obtained is further increased, the polysiloxane structure represented by SP1 is preferably a group represented by *—(Si(CH₃)₂—O)ₙ₃—*. In the formula, n3 represents an integer of 6 to 10, and * represents a bonding position to L1 or M1.

In addition, for a reason that the alignment degree of a light absorption anisotropic layer thus obtained is further increased, the alkylene fluoride structure represented by SP1 is preferably a group represented by *—(CF₂—CF₂)ₙ₄—*. In the formula, n4 represents an integer of 6 to 10, and * represents a bonding position to L1 or M1.

The mesogenic group represented by M1 is a group indicating a main skeleton of a liquid crystal molecule which contributes to liquid crystal formation. The liquid crystal molecule exhibits liquid crystallinity which is an intermediate state (mesophase) between a crystalline state and an isotropic liquid state. The mesogenic group is not particularly limited, and reference can be made to, for example, “Flussige Kristalle in Tabellen II” (VEB Deutsche Verlag fur Grundstoff Industrie, Leipzig, published in 1984), particularly the descriptions on pages 7 to 16, and Editorial committee of Liquid Crystal Handbook, liquid crystal handbook (Maruzen Publishing Co., Ltd., published in 2000), particularly the descriptions in Chapter 3.

As the mesogenic group, for example, a group having at least one kind of cyclic structure selected from the group consisting of an aromatic hydrocarbon group, a heterocyclic group, and an alicyclic group is preferable.

For a reason that the alignment degree of a light absorption anisotropic layer thus obtained is further increased, the mesogenic group preferably has aromatic hydrocarbon groups, more preferably has two to four aromatic hydrocarbon groups, and still more preferably has three aromatic hydrocarbon groups.

As the mesogenic group, a group represented by Formula (M1-A) or Formula (M1-B) is preferable, and the group represented by Formula (M1-B) is more preferable front the viewpoints of exhibition of liquid crystallinity, adjustment of a liquid crystal phase transition temperature, availability of a raw material, and synthesis suitability, and for a reason that the effect of the present invention is more excellent.

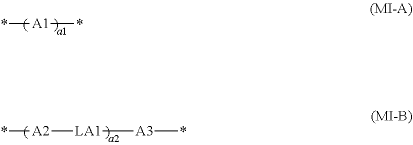

In Formula (M1-A), A1 is a divalent group selected from the group consisting of an aromatic hydrocarbon group, a heterocyclic group, and an alicyclic group. These groups may be substituted with an alkyl group, an alkyl fluoride group, an alkoxy group, or a substituent.

The divalent group represented by A1 is preferably a 4- to 6-membered ring. Moreover, the divalent group represented by A1 may be monocyclic or condensed cyclic.

* represents a bonding position to SP1 or T1.

Examples of the divalent aromatic hydrocarbon group represented by A1 include a phenylene group, a naphthylene group, a fluorene-diyl group, an anthracene-diyl group, and a tetracene-diyl group, and from the viewpoint of a diversity of design of a mesogenic skeleton, availability of a raw material, or the like, a phenylene group or a naphthylene group is preferable and a phenylene group is more preferable.

The divalent heterocyclic group represented by A1 may be either aromatic or non-aromatic, but is preferably a divalent aromatic heterocyclic group from the viewpoint that the alignment degree is further improved.

Examples of atoms which constitute the divalent aromatic heterocyclic group and are other than carbon include a nitrogen atom, a sulfur atom, and an oxygen atom. In a case where the aromatic heterocyclic group has a plurality of atoms which constitute a ring and are other than carbon, these atoms may be the same as or different from each other.

Specific examples of the divalent aromatic heterocyclic group include a pyridylene group (pyridine-diyl group), a pyridazine-diyl group, an imidazole-diyl group, thienylene (thiophene-diyl group), a quinolylene group (quinoline-diyl group), an isoquinolylene group (isoquinoline-diyl group), an oxazole-diyl group, a thiazole-diyl group, an oxadiazole-diyl group, a benzothiazole-diyl group, a benzothiadiazole-diyl group, a phthalimido-diyl group, a thienothiazole-diyl group, a thiazolothiazole-diyl group, a thienothiophene-diyl group, and a thienooxazole-diyl group.

Specific examples of the divalent alicyclic group represented by A1 include a cyclopentylene group and a cyclohexylene group.

In Formula (M1-A), a1 represents an integer of 1 to 10. In a case where a1 is 2 or more, a plurality of A1's may be the same as or different from each other.

In Formula (M1-B), A2 and A3 are each independently a divalent group selected from the group consisting of an aromatic hydrocarbon group, a heterocyclic group, and an alicyclic group. Specific examples and suitable aspects of A2 and A3 are the same as those of A1 in Formula (M1-A), and thus descriptions thereof will be omitted.

In Formula (M1-B), a2 represents an integer of 1 to 10, and in a case where a2 is 2 or more, a plurality of A2's may be the same as or different from each other, a plurality of A3's may be the same as or different from each other, and a plurality of LA1's may be the same as or different from each other. For a reason that the alignment degree of a light absorption anisotropic layer thus obtained is further increased, a2 is preferably an integer of 2 or more, and more preferably 2.

In Formula (M1-B), in a case where a2 is 1, LA1 is a divalent linking group. In a case where a2 is 2 or more, the plurality of LA1's are each independently a single bond or a divalent linking group, and at least one among the plurality of LA1's is a divalent linking group. In a case where a2 is 2, it is preferable that one of two LA1's is the divalent linking group and the other is the single bond for a reason that the alignment degree of a light absorption anisotropic layer thus obtained is further increased.

In Formula (M1-B), examples of the divalent linking group represented by LA1 include —O—, —(CH₂)_{g}—, —(CF₂)_{g}—, —Si(CH₃)₂—, —(Si(CH₃)₂O)_{g}—, —(OSi(CH₃)₂)_{g}— (g represents an integer of 1 to 10), —N(Z)—, —C(Z)═C(Z′)—, —C(Z)═N—, —N═C(Z)—, —C(Z)₂—C(Z′)₂—, —C(O)—, —OC(O)—, —C(O)O—, —O—C(O)O—, —N(Z)C(O)—, —C(O)N(Z)—, —C(Z)═C(Z′)—C(O)O—, —O—C(O)—C(Z)═C(Z′)—, —C(Z)═N—, —N═C(Z)—, —C(Z)═C(Z′)—C(O)N(Z″)—, —N(Z″)—C(O)—C(Z)═C(Z′)—, —C(Z)═C(Z′)—C(O)—S—, —S—C(O)—C(Z)═C(Z′)—, —C(Z)═N—N═C(Z′)— (Z, Z′, and Z″ independently represent a hydrogen atom, a C1 to C4 alkyl group, a cycloalkyl group, an aryl group, a cyano group, or a halogen atom), —C≡C—, —N═N—, —S—, —S(O)—, —S(O)(O)—, —(O)S(O)O—, —O(O)S(O)O—, —SC(O)—, and —C(O)S—. Among those, for a reason that the alignment degree of a light absorption anisotropic layer thus obtained is further increased, —C(O)O— is preferable. LA1 may be a group obtained by combining two or more of these groups.

Specific examples of M1 include the following structures. Moreover, in the following specific examples, “Ac” represents an acetyl group.

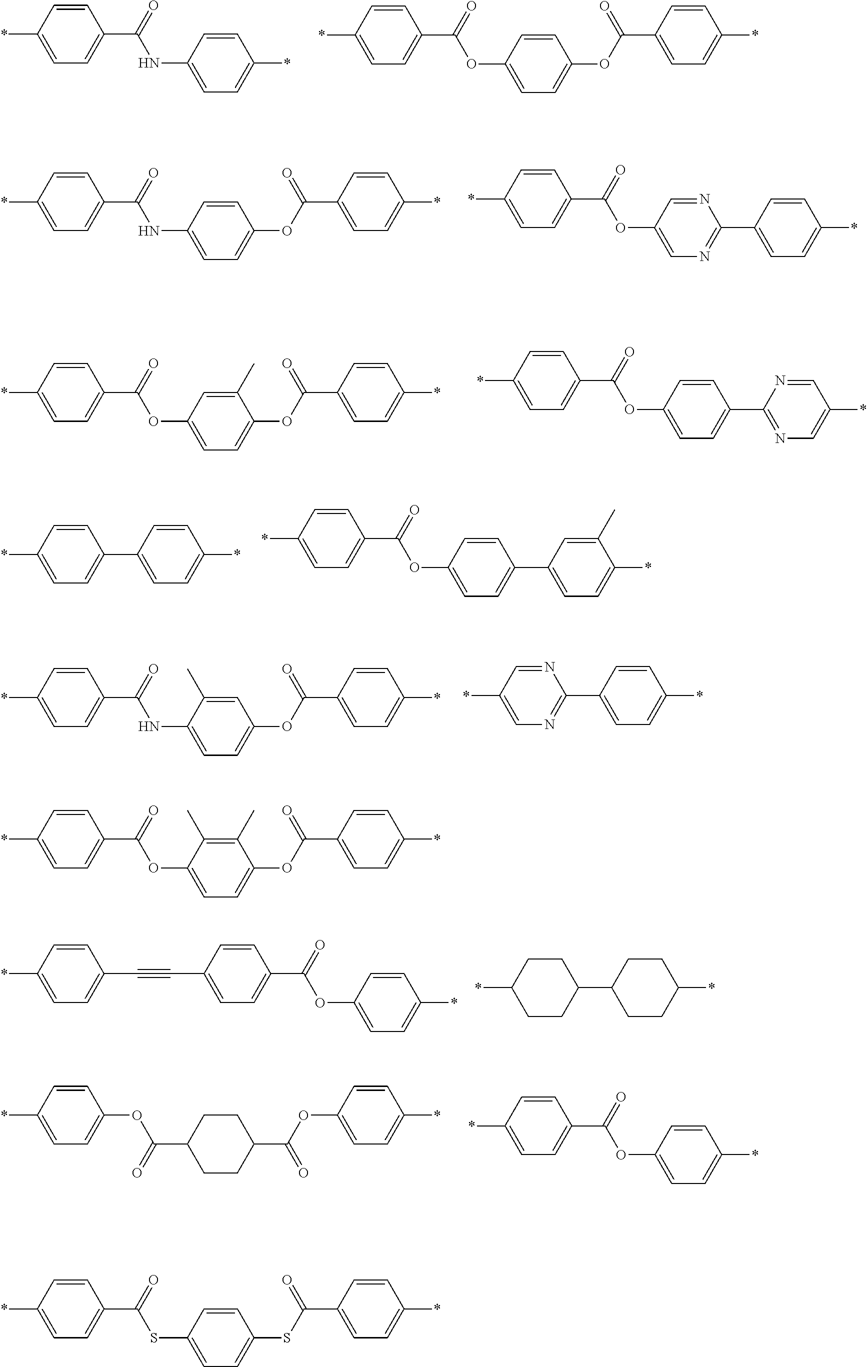

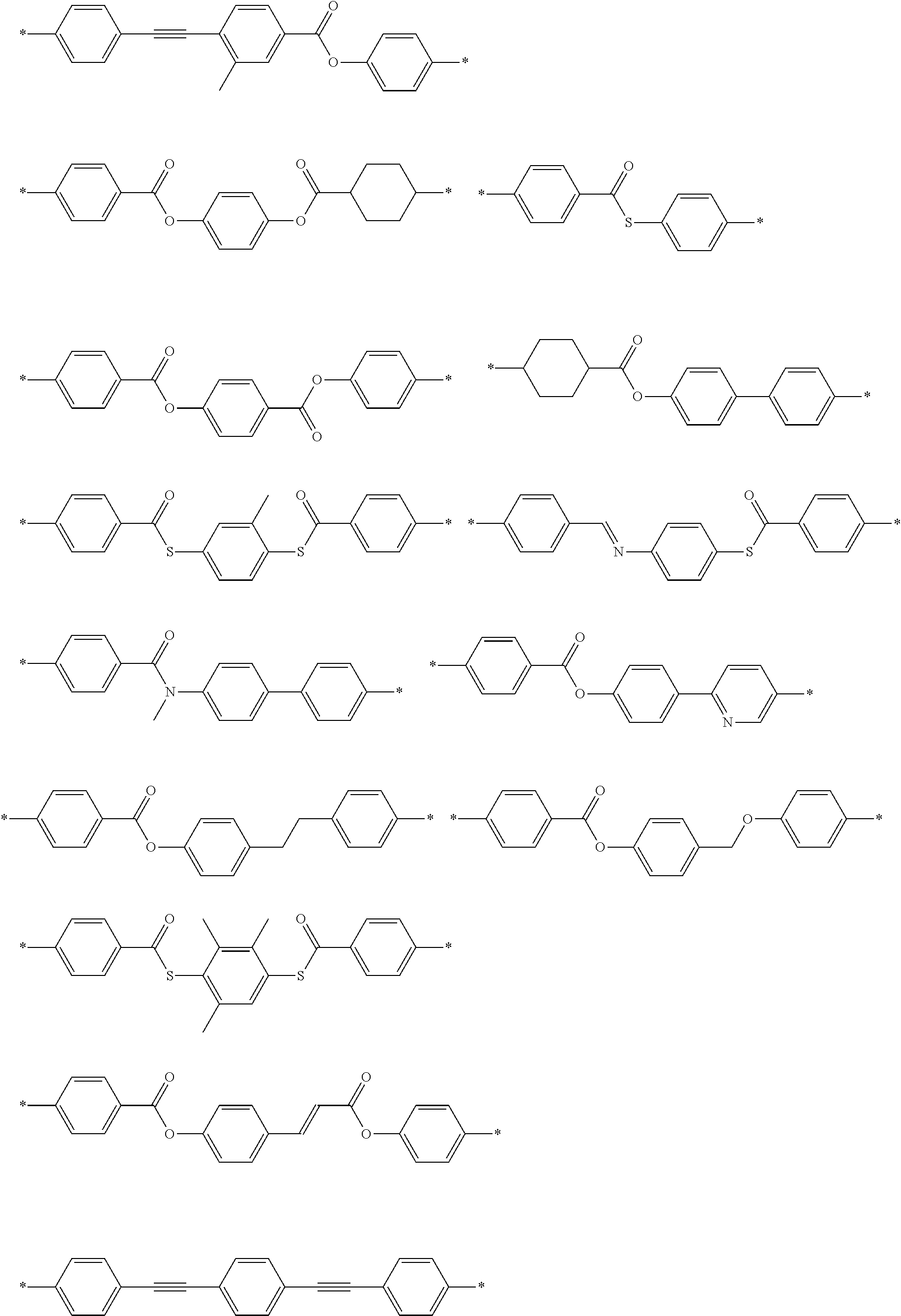

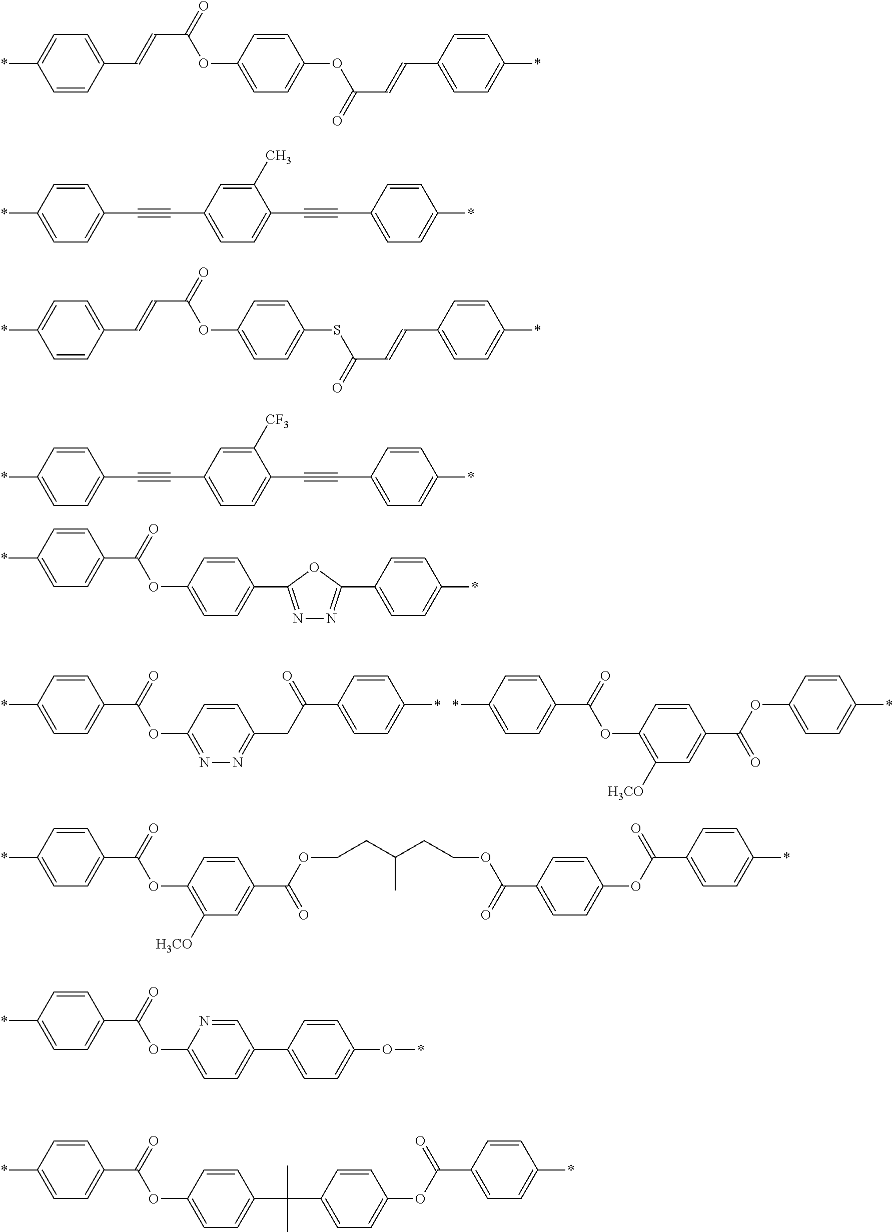

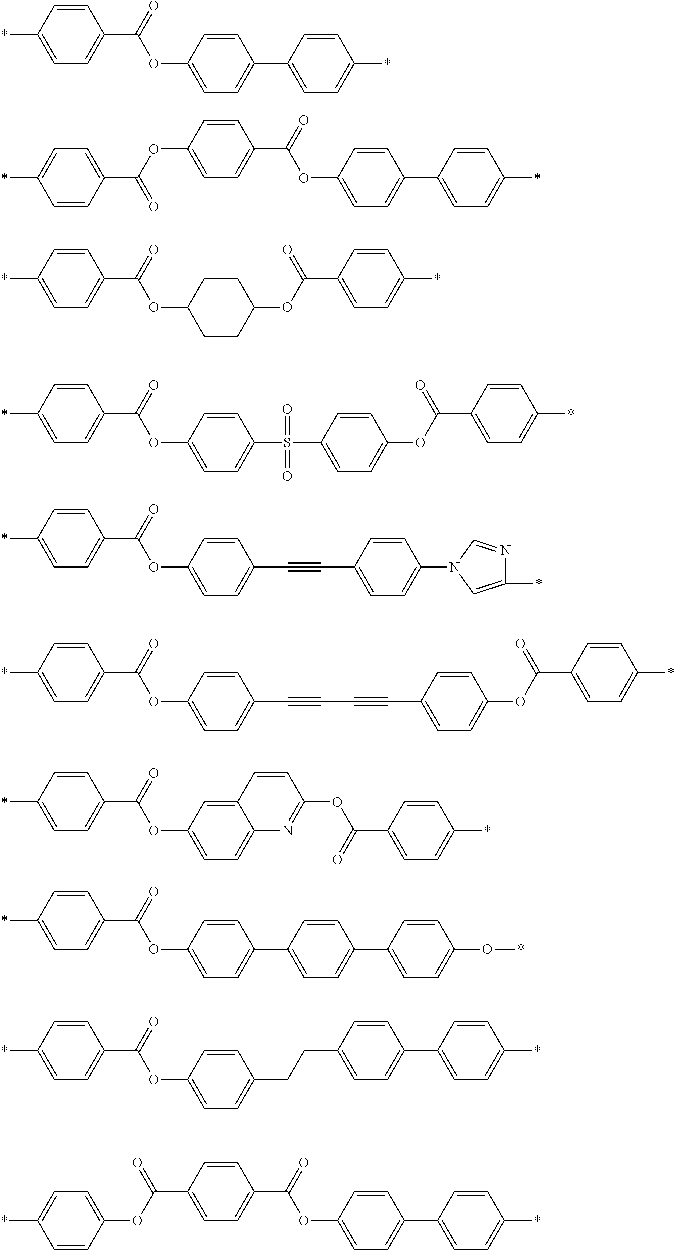

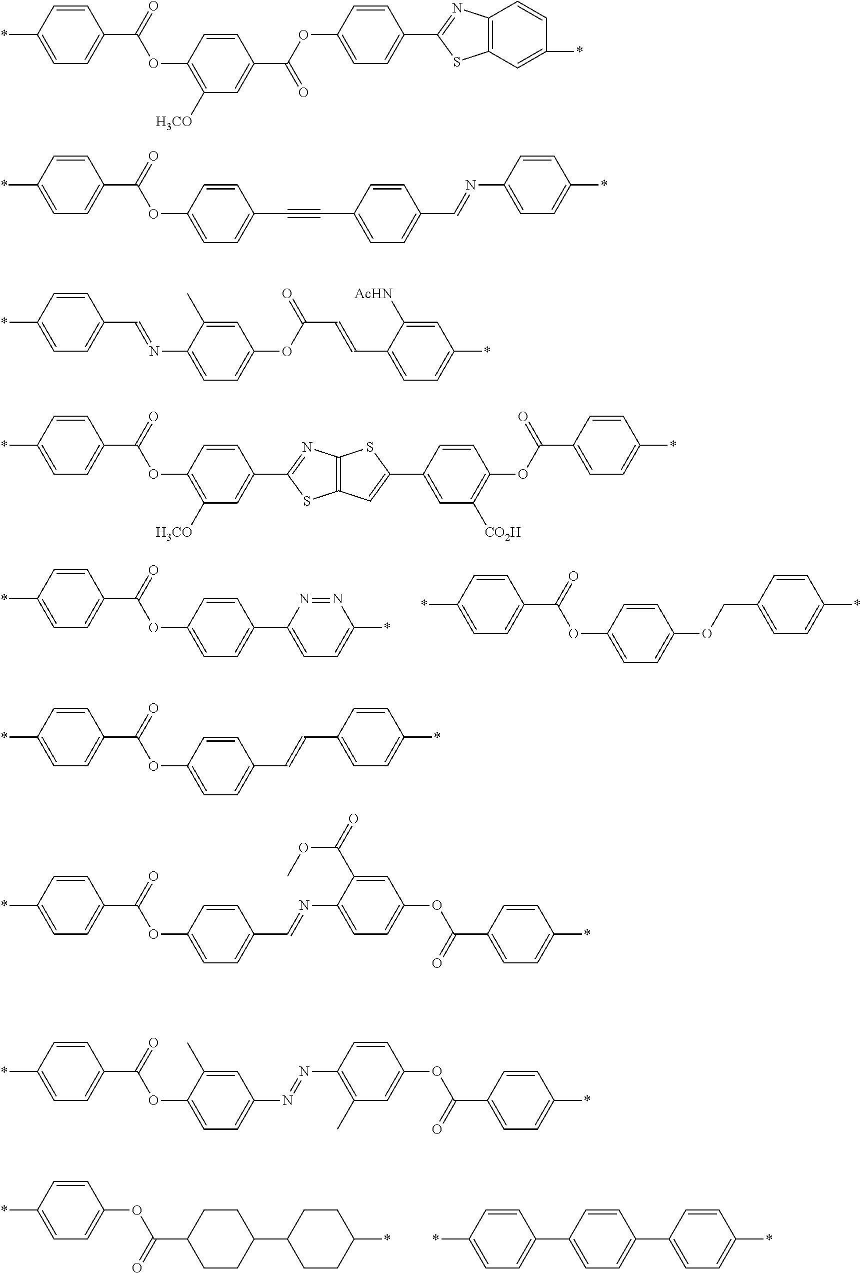

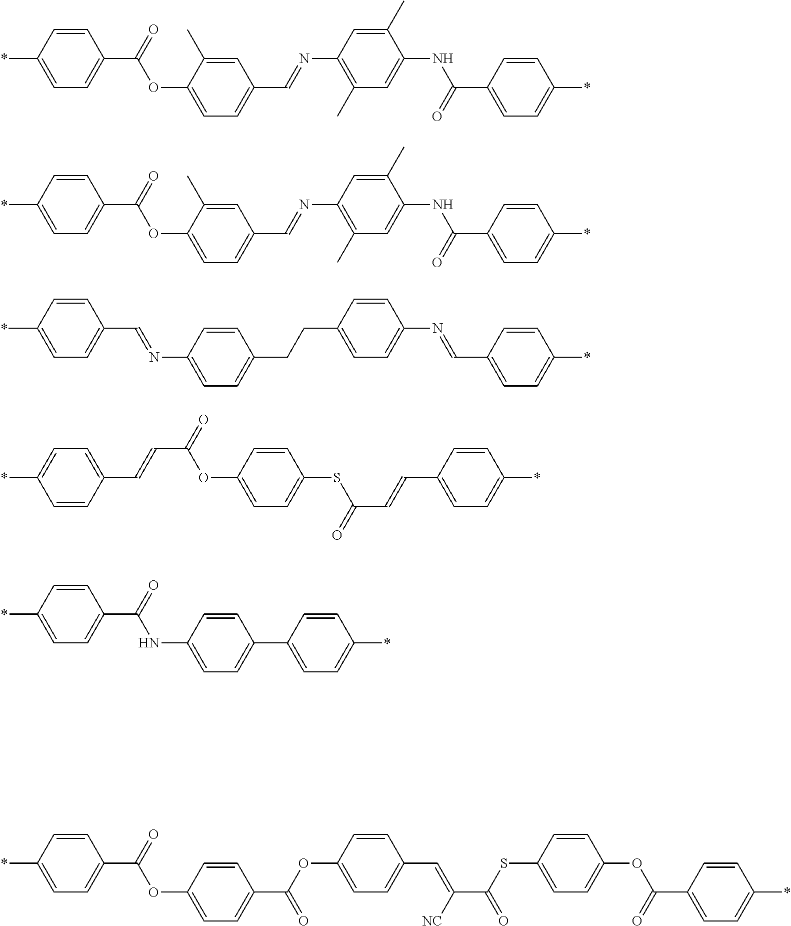

Examples of the terminal group represented by T1 include a hydrogen atom, a halogen atom, a cyano group, a nitro group, a hydroxy group, an alkyl group having 1 to 10 carbon atoms, an alkoxy group having 1 to 10 carbon atoms, an alkylthio group having 1 to 10 carbon atoms, an alkoxycarbonyloxy group having 1 to 10 carbon atoms, an alkoxycarbonyl group (ROC(O)—: R is an alkyl group) having 1 to 10 carbon atoms, an acyloxy group having 1 to 10 carbon atoms, an acylamino group having 1 to 10 carbon atoms, an alkoxycarbonylamino group having 1 to 10 carbon atoms, a sulfonylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to 10 carbon atoms, and a (meth)acryloyloxy group-containing group. Examples of the (meth)acryloyloxy group-containing group include a group represented by -L-A (L represents a single bond or a linking group, specific examples of the linking group are the same as those of L1 and SP1 described above, and A represents a (meth)acryloyloxy group).

For a reason that the alignment degree of a light absorption anisotropic layer thus obtained is further increased, T1 is preferably an alkoxy group having 1 to 10 carbon atoms, more preferably an alkoxy group having 1 to 5 carbon atoms, and still more preferably a methoxy group. These terminal groups may be further substituted with these groups or the polymerizable group described in 22010-244038A.

For a reason that the alignment degree of a light absorption anisotropic layer thus obtained is further increased, the number of atoms in the main chain of T1 is preferably 1 to 20, more preferably 1 to 15, still more preferably 1 to 10, and particularly preferably 1 to 7. In a case where the number of atoms in the main chain of T1 is 20 or less, the alignment degree of the polarizer is further improved. Here, the “main chain” in T1 means the longest molecular chain bonded to M1, and the number of hydrogen atoms is not counted as the number of atoms in the main chain of T1. For example, in a case where T1 is an n-butyl group, the number of atoms in the main chain is 4, and in a case where T1 is a sec-butyl group, the number of atoms in the main chain is 3.

For a reason that the alignment degree of a light absorption anisotropic layer thus obtained is further increased, a content of the repeating unit (1) is preferably 20% to 100% by mass with respect to 100% by mass of all repeating units in the high-molecular-weight liquid crystalline compound.

In the present invention, a content of each repeating unit included in the high-molecular-weight liquid crystalline compound is calculated based on a charged amount (mass) of each monomer used to obtain each repeating unit.

The high-molecular-weight liquid crystalline compound may include one kind of the repeating unit (1) alone or two or more kinds thereof. Among those, two kinds of the repeating units (1) are preferably included in the high-molecular-weight liquid crystalline compound for a reason that the alignment degree of a light absorption anisotropic layer thus obtained is further increased.

In a case where the high-molecular-weight liquid crystalline compound includes two kinds of the repeating units (1), for a reason that the alignment degree of a light absorption anisotropic layer thus obtained is further increased, it is preferable that the terminal group represented by T1 in one repeating unit (repeating unit A) is an alkoxy group and the terminal group represented by T1 in the other repeating unit (repeating unit B) is a group other than an alkoxy group.

For a reason that the alignment degree of a light absorption anisotropic layer thus obtained is further increased, the terminal group represented by T1 in the repeating unit B is preferably an alkoxycarbonyl group, a cyano group, or a (meth)acryloyloxy group-containing group, and more preferably an alkoxycarbonyl group or a cyano group.

For a reason that the alignment degree of a light absorption anisotropic layer thus obtained is further increased, a proportion (A/B) of the content of the repeating unit A in the high-molecular-weight liquid crystalline compound to the content of the repeating unit B in the high-molecular-weight liquid crystalline compound is preferably 50/50 to 95/5, more preferably 60/40 to 93/7, and still more preferably 70/30 to 90/10.

<Repeating Unit (3-2)>

The high-molecular-weight liquid crystalline compound of the present invention may further include a repeating unit represented by Formula (3-2) (in the present specification, this repeating unit is also referred to as a “repeating unit (3-2)”). Thus, there are advantages such as improvement in a solubility of the high-molecular-weight liquid crystalline compound in a solvent and easy adjustment of the liquid crystal phase transition temperature.

The repeating unit (3-2) is different from the repeating unit (1) in that the repeating unit (3-2) has at least no mesogenic group.

In a case where the high-molecular-weight liquid crystalline compound includes the repeating unit (3-2), the high-molecular-weight liquid crystalline compound is a copolymer including the repeating unit (1) and the repeating unit (3-2) (which may also be a copolymer including the repeating units A and B), and may be any of polymers such as a block polymer, an alternating polymer, a random polymer, and a graft polymer.

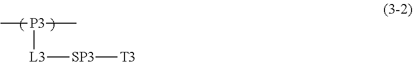

In Formula (3-2), P3 represents a main chain of the repeating unit, L3 represents a single bond or a divalent linking group, SP3 represents a spacer group, and T3 represents a terminal group.

Specific examples of P3, L3, SP3, and T3 in Formula (3-2) are the same as those of P1, L1, SP1, and T1, respectively, in Formula (1).

Here, T3 in Formula (3-2) preferably has a polymerizable group from the viewpoint that the hardness of the light absorption anisotropic layer is improved.

In a case where the repeating unit (3-2) is contained, a content thereof is preferably 0.5% to 40% by mass and more preferably 1% to 30% by mass, with respect to 100% by mass of all repeating units in the high-molecular-weight liquid crystalline compound.

The high-molecular-weight liquid crystalline compound may include one kind of repeating unit (3-2) alone, or two or more kinds thereof. In a case where the two or more kinds of the repeating units (3-2) are included, a total amount thereof is preferably in the range.

(Weight-Average Molecular Weight)

For a reason that the alignment degree of a light absorption anisotropic layer thus obtained is further increased, a weight-average molecular weight (Mw) of the high-molecular-weight liquid crystalline compound is preferably 1,000 to 500,000 and more preferably 2,000 to 300,000. In a case where the Mw of the high-molecular-weight liquid crystalline compound is in the range, handling of the high-molecular-weight liquid crystalline compound is easy.

In particular, from the viewpoint of suppression of cracks during application, the weight-average molecular weight (Mw) of the high-molecular-weight liquid crystalline compound is preferably 10,000 or more, and more preferably 10,000 to 300,000.

In addition, from the viewpoint of a temperature latitude of the alignment degree, the weight-average molecular weight (Mw) of the high-molecular-weight liquid crystalline compound is preferably less than 10,000 and more preferably 2,000 or more and less than 10,000.

Here, the weight-average molecular weight and the number-average molecular weight in the present invention are values measured by a gel permeation chromatography (GPC) method.
Solvent (eluent): N-Methylpyrrolidone
Device name: TOSOH HLC-8220GPC
Column: Three columns of TOSOH TSKgel Super AWM-H (6 mm×15 cm) connected to each other are used
Column temperature: 25° C.
Sample concentration: 0.1% by mass
Flow rate: 0.35 mL/min
Calibration curve: Calibration curve obtained from seven samples of TSK standard polystyrene Mw of 2,800,000 to 1,050 (Mw/Mn=1.03 to 1.06) manufactured by Tosoh Corporation is used

(Content)

In the present invention, a content of the liquid crystalline compound is preferably an amount of 50% to 99% by mass, and preferably an amount of 70% to 96% by mass in the solid content of the composition for forming a light absorption anisotropic layer.

Here, the “solid content in the composition for forming a light absorption anisotropic layer” refers to a component excluding a solvent, and specific examples of the solid content include the liquid crystalline compound, a dichroic substance which will be described later, a polymerization initiator, and an interface modifier.

<Dichroic Substance>

The composition for forming a light absorption anisotropic layer used in the present invention contains a dichroic substance.

The dichroic substance is not particularly limited, and is a visible light absorbing substance (dichroic coloring agent), a luminescent substance (a fluorescent substance, a phosphorescent substance), an ultraviolet absorbing substance, an infrared absorbing substance, a nonlinear optical substance, a carbon nanotube, and an inorganic substance (for example, a quantum rod), and dichroic substances (dichroic coloring agents) known in the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, paragraphs [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, and the like.

In the present invention, two or more dichroic substances may be used in combination, and for example, from the viewpoint of bringing a light absorption anisotropic layer thus obtained closer to black, it is preferable to use at least one dichroic substance having a maximum absorption wavelength in the wavelength range of 370 to 550 nm and at least one dichroic substance having a maximum absorption wavelength in the wavelength range of 500 to 700 nm in combination.

In this case, the light absorption anisotropic layer having a dichroic substance can also be used as a polarizer.

The dichroic substance may have a crosslinkable group. In particular, from the viewpoint of suppressing a change in the degree of polarization during heating, it is preferable that the dichroic substance has a crosslinkable group.

Specific examples of the crosslinkable group include a (meth)acryloyl group, an epoxy group, an oxetanyl group, and a styryl group, and among these, the (meth)acryloyl group is preferable.

(Content)

For a reason that the alignment degree of the dichroic substance is further increased, a content of the dichroic substance of the composition for forming a light absorption anisotropic layer is preferably 1 to 400 parts by mass, more preferably 2 to 100 parts by mass, and still more preferably 5 to 30 parts by mass with respect to 100 parts by mass of the liquid crystalline compound.

<Surfactant>

As the surfactant contained in the composition for forming a light absorption anisotropic layer, a surfactant known in the related art can be used, but a copolymer having a repeating unit including an alkyl fluoride group (hereinafter also simply referred to as a “repeating unit F”) and a repeating unit including a ring structure (hereinafter also simply referred to as a “repeating unit M”) is preferable.

For a Hansen solubility parameter, a value calculated by inputting a structural formula of a compound into HSPiP (Ver. 5.1.08) was adopted. The variance term δD is a term due to the van der Waals force.

Furthermore, in a copolymer, δD and the volume are calculated by a structural formula in which a bonding moiety of each repeating unit is substituted with a hydrogen atom, and a value averaged by the volume ratio is adopted.

High-temperature aging at 80° C. to 140° C. is required to align liquid crystals, and the viscosity of the composition may be decreased during the high-temperature aging, resulting in cissing failure. As a result of the investigations conducted by the present inventors, it was clarified that there is a correlation between the δD of the surfactant and the cissing failure. Specifically, the δD of the surfactant is preferably from 15.5 to 17.5, and more preferably from 15.8 to 17.0.

(Repeating Unit F)

The repeating unit F contained in the copolymer is preferably a repeating unit represented by Formula (a).

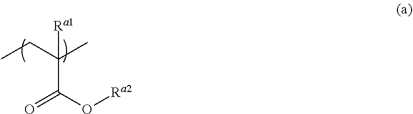

In Formula (a), R^{a1} represents a hydrogen atom or an alkyl group having 1 to 20 carbon atoms, and R^{a2} represents an alkyl group having 1 to 20 carbon atoms or an alkenyl group having 2 to 20 carbon atoms, in which at least one carbon atom has a fluorine atom as a substituent.

For a reason that the alignment defects of the obtained light absorption anisotropic layer are further suppressed, R^{a2} in Formula (a) is preferably an alkyl group having 1 to 10 carbon atoms or alkenylene group having 2 to 10 carbon atoms, in which at least one carbon atom has a fluorine atom as a substituent, more preferably the alkyl group having 1 to 10 carbon atoms, and particularly preferably the group in which a half or more of the number of carbon atoms included in R^{a2} have fluorine atoms as a substituent.

In the present invention, the repeating unit F contained in the copolymer is more preferably a repeating unit represented by Formula (b).

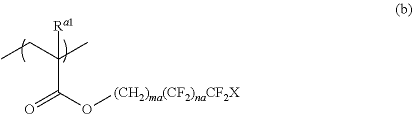

In Formula (b), R^{a1} represents a hydrogen atom or an alkyl group having 1 to 20 carbon atoms, ma and na each independently represent an integer of 0 or more, and X represents a hydrogen atom or a fluorine atom.

Here, ma is preferably an integer from 1 to 10, and na is preferably an integer from 4 to 12.

Specific examples of a monomer (hereinafter also simply referred to as a “fluoroalkyl group-containing monomer”) that forms the repeating unit F contained in the copolymer include 2,2,2-trifluoroethyl (meth)acrylate, 2,2,3,3,3-pentafluoropropyl (meth)acrylate, 2-(perfluorobutyl)ethyl (meth)acrylate, 2-(perfluorohexyl)ethyl (meth)acrylate, 2-(perfluorooctyl)ethyl (meth)acrylate, 2-(perfluorodecyl)ethyl (meth)acrylate, 2-(perfluoro-3-methylbutyl)ethyl (meth)acrylate, 2-(perfluoro-5-methylhexyl)ethyl (meth)acrylate, 2-(perfluoro-7-methyloctyl)ethyl (meth)acrylate, 1H,1H,3H-tetrafluoropropyl (meth)acrylate, 1H,1H,5H-octafluoropentyl (meth)acrylate, 1H,1H,7H-dodecafluoroheptyl (meth)acrylate, 1H,1H,9H-hexadecafluorononyl (meth)acrylate, 1H-1-(trifluoromethyl)trifluoroethyl (meth)acrylate, 1H,1H,3H-hexafluorobutyl (meth)acrylate, 3-perfluorobutyl-2-hydroxypropyl (meth)acrylate, 3-perfluorohexyl-2-hydroxypropyl (meth)acrylate, 3-perfluorooctyl-2-hydroxypropyl (meth)acrylate, 3-(perfluoro-3-methylbutyl)-2-hydroxypropyl (meth)acrylate, 3-(perfluoro-5-methylhexyl)-2-hydroxypropyl (meth)acrylate, and 3-(perfluoro-7-methyloctyl)-2-hydroxypropyl (meth)acrylate.

In the present invention, a proportion of copolymerizing the fluoroalkyl group-containing monomers is preferably 0.01 to 100 moles, more preferably 0.1 to 50 mole, and still more preferably 1 to 30 moles with respect to 1 mole of the monomer having a mesogenic group which will be described, from the viewpoint of the reactivity and the surface modification effect.

(Repeating Unit M)

The repeating unit M contained in the copolymer only needs to be a unit including a ring structure.

The ring structure represents, for example, at least one ring structure selected from the group consisting of an aromatic hydrocarbon group, a heterocyclic group, and an alicyclic group. From the viewpoint of suppressing alignment defects, it is preferable to have two or more ring structures.

In the present invention, the repeating unit F contained in the copolymer is more preferably a repeating unit represented by Formula (c).

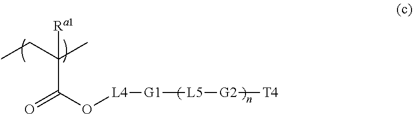

In Formula (c), R^{a1} represents a hydrogen atom or an alkyl group having 1 to 20 carbon atoms, L4 and L5 each represent a single bond or an alkylene group having 1 to 8 carbon atoms, G1 and G2 each represent a divalent cyclic group, and T1 represents a terminal group. n represents an integer of 0 to 4.

In the alkylene group represented by each of L4 and L5, one or more —CH₂—'s constituting the alkylene group may be substituted with at least one group selected from the group consisting of a single bond, —O—, —S—, —NR³¹—, —C(═O)—, —C(═S)—, —CR³²═CR³²—, —C≡C—, —SiR³³R³⁴—, —N═N—, —CR³⁵═N—N═CR³⁶—, —CR³⁷═N—, and —SO₂—, and R³¹ to R³⁷ each independently represent a hydrogen atom, a halogen atom, a cyano group, a nitro group, or a linear or branched alkyl group having 1 to 10 carbon atoms.

In addition, in a case where L represents an alkylene group, a hydrogen atom included in one or more —CH₂—'s constituting the alkylene group may be substituted with at least one group selected from the group consisting of a halogen atom, a cyano group, a nitro group, a hydroxyl group, a linear alkyl group having 1 to 10 carbon atoms, and a branched alkyl group having 1 to 10 carbon atoms.

Among those, L4 is preferably an alkyleneoxy group having 4 to 6 carbon atoms with oxygen at a terminal, and L5 is most preferably an ester group.

The divalent cyclic groups represented by G1 and G2 each independently represent a divalent alicyclic hydrocarbon group or aromatic hydrocarbon group having 5 to 8 carbon atoms, and one or more of —CH₂—'s constituting the alicyclic hydrocarbon group may be substituted with —O—, —S—, or —NH—. Further, a plurality of the alicyclic hydrocarbon groups or the aromatic hydrocarbon groups may be single-bonded. Among these, a benzene ring is preferable.

Examples of the terminal group represented by T4 include a hydrogen atom, a halogen atom, a cyano group, a nitro group, a hydroxy group, an alkyl group having 1 to 10 carbon atoms, an alkoxy group having 1 to 10 carbon atoms, an alkyl thio group having 1 to 10 carbon atoms, an alkoxycarbonyloxy group having 1 to 10 carbon atoms, an alkoxycarbonyl group (ROC(O)—: R is an alkyl group) having 1 to 10 carbon atoms, an acyloxy group having 1 to 10 carbon atoms, an acylamino group having 1 to 10 carbon atoms, an alkoxycarbonylamino group having 1 to 10 carbon atoms, a sulforylamino group having 1 to 10 carbon atoms, a sulfamoyl group having 1 to 10 carbon atoms, a carbamoyl group having 1 to 10 carbon atoms, a sulfinyl group having 1 to 10 carbon atoms, a ureide group having 1 to 10 carbon atoms, and a (meth)acryloyloxy group-containing group. Among these, the hydrogen atom or the cyano group is the most preferable.

A molar ratio of the repeating units F to all repeating units is preferably 50% by mole or more from the viewpoint of the alignment degree, and is preferably 70% by mole or less from the viewpoint of cissing.

(Content)

in the present invention, for a reason that the alignment degree of a light absorption anisotropic layer thus obtained is further increased, a content of the above-mentioned surfactant is preferably 0.05 to 15 parts by mass, more preferably 0.08 to 10 parts by mass, and still more preferably 0.1 to 5 parts by mass with respect to 100 parts by mass of the liquid crystalline compound.

<Polymerization Initiator>

The composition for forming a light absorption anisotropic layer preferably includes a polymerization initiator.

The polymerization initiator is not particularly limited, but is preferably a photosensitive compound, that is, a photopolymerization initiator.

As the photopolymerization initiator, various kinds of compounds can be used with no particular limitation. Examples of the photopolymerization initiator include the α-carbonyl compound (each of the specifications of U.S. Pat. No. 2,367,661A and U.S. Pat. No. 2,367,670A), the acyloin ether (the specification of U.S. Pat. No. 2,448,828A), the α-hydrocarbon-substituted aromatic acyloin compound (the specification of U.S. Pat. No. 2,722,512A), the polynuclear quinone compound (each of the specifications of U.S. Pat. No. 3,046,127A and U.S. Pat. No. 2,951,758A), the combination of a triarylimidazole dimer and p-aminophenyl ketone (the specification of U.S. Pat. No. 3,549,367A), the acridine and phenazine compounds (JP1985-105667A (JP-S60-105667A) and the specification of U.S. Pat. No. 4,239,850A), the oxadiazole compound (the specification of U.S. Pat. No. 4,212,970A), the o-acyloxime compounds ([0065] of JP2016-27384A), and the acyl phosphine oxide compounds (JP1988-40799B (JP-S63-40799B), JP1993-29234B (JP-H05-29234B), JP1998-95788A (JP-H10-95788A), and JP1998-29997A (JP-H10-29997A)).

A commercially available product can also be used as such a photopolymerization initiator, and examples thereof include IRGACURE-184, IRGACURE-907, IRGACURE-369, IRGACURE-651, IRGACURE-819, IRGACURE-OXE-01, and IRGACURE-OXE-02, manufactured by BASF SF.

In a case where the composition for forming a light absorption anisotropic layer contains a polymerization initiator, a content of the polymerization initiator is preferably 0.01 to 30 parts by mass, and more preferably 0.1 to 15 parts by mass with respect to 100 parts by mass of a total amount of the dichroic substance and the liquid crystalline compound in the composition for forming a light absorption anisotropic layer. In a case where the content of the polymerization initiator is 0.01 parts by mass or more, the durability of the light absorption anisotropic film is good, whereas in a case where the content of the polymerization initiator is 30 parts by mass or less, the alignment degree of the light absorption anisotropic film is better.

The polymerization initiators may be used alone or in combination of two or more kinds thereof. In a case where the two or more kinds of the polymerization initiators are included, a total amount thereof is preferably in the range.

<Solvent>

The coloring composition for forming a light absorption anisotropic layer of the embodiment of the present invention preferably contains a solvent from the viewpoint of workability and the like.

Examples of the solvent include organic solvents such as ketones (for example, acetone, 2-butanone, methyl isobutyl ketone, cyclopentanone, and cyclohexanone), ethers (for example, dioxane, tetrahydrofuran, 2-methyltetrahydrofuran, cyclopentylmethyl ether, tetrahydropyran, and dioxolane), aliphatic hydrocarbons (for example, hexane), alicyclic hydrocarbons (for example, cyclohexane), aromatic hydrocarbons (for example, benzene, toluene, xylene, and trimethylbenzene), halogenated carbons (for example, dichloromethane, trichloromethane, dichloroethane, dichlorobenzene, and chlorotoluene), esters (for example, methyl acetate, ethyl acetate, butyl acetate, and ethyl lactate), alcohols (for example, ethanol, isopropanol, butanol, cyclohexanol, isopentyl alcohol, neopentyl alcohol, diacetone alcohol, and benzyl alcohol), cellosolves (for example, methyl cellosolve, ethyl cellosolve, and 1,2-dimethoxyethane), cellosolve acetates, sulfoxides (for example, dimethyl sulfoxide), amides (for example, dimethylformamide, dimethylacetamide, N-methylpyrrolidone, and N-ethylpyrrolidone), and heterocyclic compounds (for example, pyridine), and water. These solvents may be used alone or in combination of two or more kinds thereof.

Among these solvents, ketones (in particular, cyclopentanone and cyclohexanone), ethers (in particular, tetrahydrofuran, cyclopentylmethyl ether, tetrahydropyran, and dioxolane), and amides (in particular, dimethylformamide, dimethylacetamide, N-methylpyrrolidone, and N-ethylpyrrolidone) are preferable from the viewpoint of utilizing the effect of excellent solubility.

In a case where the composition for forming a light absorption anisotropic layer contains a solvent, a content of the solvent is preferably 80% to 99% by mass, more preferably 83% to 97% by mass, and particularly preferably 85% to 95% by mass with respect to the total mass of the composition for forming a light absorption anisotropic layer.

The solvents may be used alone or in combination of two or more kinds thereof. In a case where the two or more kinds of the solvents are included, a total amount thereof is preferably in the range.

<Method of Forming Light Absorption Anisotropic Layer>

A method for forming the light absorption anisotropic layer is not particularly limited, and examples thereof include a method including a step of applying the above-mentioned composition for forming a light absorption anisotropic layer onto an alignment layer which will be described later to form a coating film (hereinafter also referred to as a “coating film forming step”) and a step of aligning the liquid crystalline components or the dichroic substance included in the coating film (hereinafter also referred to as an “aligning step”) in this order.

Furthermore, the liquid crystalline component is a component including not only the above-mentioned liquid crystalline compound but also a liquid crystal dichroic substance in a case where the above-mentioned dichroic substance has liquid crystallinity.

(Coating Film Forming Step)

The coating film forming step is a step of applying a composition for forming a light absorption anisotropic layer onto an alignment layer which will be described later to form a coating film.

By using the composition for forming a light absorption anisotropic layer, containing the above-mentioned solvent, or by using the composition for forming a light absorption anisotropic layer formed into a liquid state material such as a molten liquid by heating or the like, it is easier to apply the composition for forming a light absorption anisotropic layer onto the alignment layer which will be described later.

Specific examples of a method for applying the composition for forming a light absorption anisotropic layer include known methods such as a roll coating method, a gravure printing method, a spin coating method, a wire bar coating method, an extrusion coating method, a direct gravure coating method, a reverse gravure coating method, a die-coating method, a spray method, and an ink jet method.

(Aligning Step)

The aligning step is a step of aligning the liquid crystalline components included in the coating film. Thus, a light absorption anisotropic layer can be obtained.

The aligning step may have a drying treatment. By the drying treatment, components such as a solvent can be removed from the coating film. The drying treatment may be performed by a method of leaving the coating film at room temperature for a predetermined time (for example, natural drying), or may be performed by a method of heating and/or blowing.

Here, the liquid crystalline component included in the composition for forming a light absorption anisotropic layer may be aligned by the above-mentioned coating film forming step or drying treatment in some cases. For example, in an aspect in which the composition for forming a light absorption anisotropic layer is prepared as a coating liquid including a solvent, a coating film having light absorption anisotropy (that is, a light absorption anisotropic film) can be obtained by drying the coating film and removing the solvent from the coating film.

In a case where the drying treatment is performed at a temperature no lower than the transition temperature of the liquid crystalline component included in the coating film to a liquid crystal phase, a heating treatment which will be described later may not be carried out.

The transition temperature of the liquid crystalline component included in the coating film to the liquid crystal phase is preferably 10° C. to 250° C., and more preferably 25° C. to 190° C., from the viewpoint of manufacturing suitability and the like. In a case where the transition temperature is 10° C. or higher, a cooling treatment or the like for lowering the temperature to a temperature range in which a liquid crystal phase is exhibited is not required, which is thus preferable, In addition, in a case where the transition temperature is 250° C. or lower, a high temperature is not required even in a case where the liquid crystal phase is once brought into an isotropic liquid state at a higher temperature than the temperature range in which a liquid crystal phase is exhibited, which is thus preferable since waste of thermal energy, and deformation, deterioration, or the like of a substrate can be reduced.

The aligning step preferably has a heating treatment. By the heating treatment, the liquid crystalline component included in the coating film can be aligned, and therefore, the coating film after the heating treatment can be suitably used as the light absorption anisotropic film.

The heating treatment is preferably performed at 10° C. to 250° C., and more preferably performed at 25° C. to 190° C., from the viewpoint of manufacturing suitability and the like. In addition, the heating time is preferably 1 to 300 seconds, and more preferably 1 to 60 seconds.

The aligning step may have a cooling treatment which is carried out after the heating treatment. The cooling treatment is a treatment for cooling the heated coating film to approximately room temperature (20° C. to 25° C.). By the cooling treatment, the alignment of the liquid crystalline component included in the coating film can be immobilized. The cooling unit is not particularly limited, and can be carried out by a known method.

Through the steps above, a light absorption anisotropic film can be obtained.

In addition, in the present aspect, examples of the method for aligning the liquid crystalline component included in the coating film include, but are not limited to, the drying treatment, the heating treatment, and the like, and the method can be carried out by a known alignment treatment.

(Other Steps)

A method for forming the light absorption anisotropic layer may have a step of curing the light absorption anisotropic layer (hereinafter also referred to as a “curing step”) after the aligning step.

For example, in a case where the light absorption anisotropic layer has a crosslinkable group (polymerizable group), the curing step is carried out by heating and/or light irradiation (exposure). Among these, the curing step is preferably carried out by light irradiation.

Various light sources such as infrared light, visible light, and ultraviolet rays can be used as a light source for curing, but the ultraviolet rays are preferable. In addition, the ultraviolet rays may be irradiated while heating at the time of curing or the ultraviolet rays may be irradiated through a filter which transmits only a specific wavelength.

In a case where the exposure is performed while heating, the heating temperature at the time of exposure depends on the transition temperature of the liquid crystalline component included in the liquid crystal film to the liquid crystal phase, but is preferably 25° C. to 140° C.

In addition, the exposure may be performed in a nitrogen atmosphere. In a case where curing of the liquid crystal film proceeds by radical polymerization, it is preferable that exposure is performed in a nitrogen atmosphere since inhibition of polymerization by oxygen is reduced.

A thickness of the light absorption anisotropic layer is not particularly limited, but is preferably 100 to 8,000 nm, and more preferably 300 to 5,000 nm from the viewpoint of the flexibility in a case where the laminate of the embodiment of the present invention, which will be described later, is used for a polarizing element.

[Vertically Aligned Light Absorption Anisotropic Layer]

In the light absorption anisotropic layer of the present invention, the dichroic substance may be horizontally aligned or vertically aligned. The vertically aligned light absorption anisotropic layer has a characteristic of absorbing polarized light incident in an oblique direction, and can be used as a privacy film for controlling a viewing angle.

From the viewpoint of vertically aligning the dichroic substance and the liquid crystal compound, it is preferable to use the following vertical alignment agent.

(Vertical Alignment Agent)

Examples of the vertical alignment agent include a boronic acid compound and an onium salt.

A compound represented by Formula (30) is preferable as the boronic acid compound.

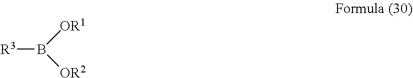

In Formula (30), R¹ and R² each independently represent a hydrogen atom, a substituted or unsubstituted aliphatic hydrocarbon group, a substituted or unsubstituted aryl group, or a substituted or unsubstituted heterocyclic group.

R³ represents a substituent including a (meth)acrylic group.

Specific examples of the boronic acid compound include the boronic acid compound represented by General Formula (I) described in paragraphs 0023 to 0032 of JP2008-225281A.

As the boronic acid compound, compounds exemplified below are also preferable.

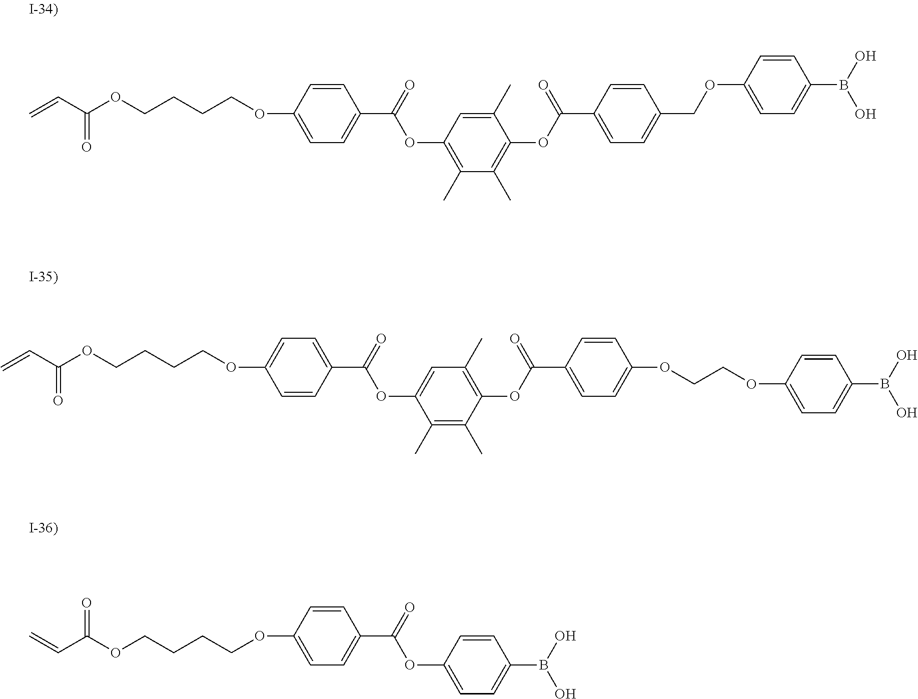 [SMILES: C=CC(=O)OCCCCOc1ccc(C(=O)Oc2cc(C)c(OC(=O)c3ccc(COc4ccc(B(O)O)cc4)cc3)c(C)c2C)cc1 ; C=CC(=O)OCCCCOc1ccc(C(=O)Oc2cc(C)c(OC(=O)c3ccc(OCCOc4ccc(B(O)O)cc4)cc3)c(C)c2C)cc1 ; C=CC(=O)OCCCCOc1ccc(C(=O)Oc2ccc(B(O)O)cc2)cc1]

As the onium salt, a compound represented by Formula (31) is preferable.

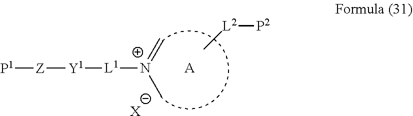

In Formula (31), the ring A represents a quaternary ammonium ion consisting of a nitrogen-containing heterocycle. X represents an anion. L¹ represents a divalent linking group. L² represents a single bond or a divalent linking group. Y¹ represents a divalent linking group having a 5- or 6-membered ring as a partial structure. Z represents a divalent linking group having 2 to 20 alkylene groups as a partial structure. P¹ and P² each independently represent a monovalent substituent having a polymerizable and ethylenically unsaturated bond.

Specific examples of the onium salt include the onium salts described in paragraphs 0052 to 0058 of JP2012-208397A, the onium salts described in paragraphs 0024 to 0055 of JP2008-026730A, and the onium salts described in JP2002-37777A.

A content of the vertical alignment agent in the composition is preferably 0.1% to 400% by mass, and more preferably 0.5% to 350% by mass with respect to the total mass of the liquid crystalline compound.

The vertical alignment agents may be used alone or in combination of two or more kinds thereof. In a case where two or more kinds of vertical alignment agents are used, a total amount thereof is preferably in the range.

(Leveling Agent Suitable for Vertical Alignment)

In the case of vertical alignment, it is preferable to include the following leveling agents. In a case where the composition includes a leveling agent, a surface roughness due to dry air applied to a surface of the light absorption anisotropic layer is suppressed and the dichroic substance is more uniformly aligned.

The leveling agent is not particularly limited, and is preferably a leveling agent including a fluorine atom (fluorine-based leveling agent) or a leveling agent including a silicon atom (silicon-based leveling agent), and more preferably the fluorine-based leveling agent.

Examples of the fluorine-based leveling agent include fatty acid esters of polyvalent carboxylic acids, in which a part of a fatty acid is substituted with a fluoroalkyl group, and polyacrylates having a fluoro substituent. In particular, in a case where a rod-like compound is used as the dichroic substance and the liquid crystalline compound, a leveling agent including a repeating unit derived from a compound represented by Formula (40) is preferable from the viewpoint of promoting the vertical alignment of the dichroic: substance and the liquid crystalline compound.

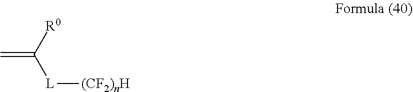

R⁰ represents a hydrogen atom, a halogen atom, or a methyl group.

L represents a divalent linking group. As L, an alkylene group having 2 to 16 carbon atoms is preferable, and any —CH₂— which is not adjacent to the alkylene group may be substituted with —O—, —COO—, —CO—, or —CONH—.

n represents an integer of 1 to 18.

The leveling agent having a repeating unit derived from the compound represented by Formula (40) may further include another repeating unit.

Examples of the other repeating unit include a repeating unit derived from a compound represented by Formula (41).

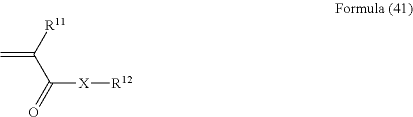

R¹¹ represents a hydrogen atom, a halogen atom, or a methyl group.

X represents an oxygen atom, a sulfur atom, or —N(R¹³)—. R¹² represents a hydrogen atom or an alkyl group having 1 to 8 carbon atoms.

R¹² represents a hydrogen atom, an alkyl group which may have a substituent, or an aromatic group which may have a substituent. The alkyl group preferably has 1 to 20 carbon atoms. The alkyl group may be any of linear, branched, and cyclic forms.

In addition, examples of the substituent which may be contained in the alkyl group include a poly(alkyleneoxy) group and a polymerizable group. The definition of the polymerizable group is the same as mentioned above.

In a case where the leveling agent includes a repeating unit derived from the compound represented by Formula (40) and the repeating unit derived from the compound represented by Formula (41), the content of the repeating unit derived from the compound represented by Formula (40) is preferably 10% to 90% by mole, and more preferably 15% to 95% by mole with respect to all the repeating units included in the leveling agent.

In a case where the leveling agent includes a repeating unit derived from the compound represented by Formula (40) and the repeating unit derived from the compound represented by Formula (41), the content of the repeating unit derived from the compound represented by Formula (41) is preferably 10% to 90% by mole, and more preferably 5% to 85% by mole with respect to all the repeating units included in the leveling agent.

In addition, examples of the leveling agent also include a leveling agent including a repeating unit derived from the compound represented by Formula (42) instead of the repeating unit derived from the compound represented by Formula (40).

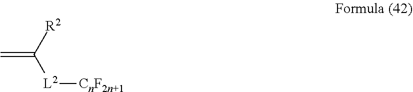

R² represents a hydrogen atom, a halogen atom, or a methyl group.

L² represents a divalent linking group.

n represents an integer of 1 to 18.

Specific examples of the leveling agent include the compounds exemplified in paragraphs 0046 to 0052 of JP2004-331812A and the compounds described in paragraphs 0038 to 0052 of JP2008-257205A.

A content of the leveling agent in the composition is preferably 10% to 80% by mass, and more preferably 20% to 60% by mass with respect to the total mass of the liquid crystalline compound.

The leveling agents may be used alone or in combination of two or more kinds thereof. In a case where two or more kinds of leveling agents are used, a total amount thereof is preferably in the range.

[Alignment Layer]

The laminate of the embodiment of the present invention preferably has an alignment layer in order to align the above-mentioned liquid crystals.

Examples of a method for forming an alignment layer include methods such as a rubbing treatment of an organic compound (preferably, a polymer) on a film surface, oblique vapor deposition of an inorganic compound, formation of a layer having microgrooves, and accumulation of an organic compound (for example, ω-tricosanoic acid, dioctadecyl methylammonium chloride, methyl stearate, and the like) by a Langmuir-Blodgett method (LB film). Moreover, an alignment layer in which an alignment function is generated by application of an electric field, application of a magnetic field, or light irradiation is also known.

Among those, in the present invention, an alignment layer formed by a rubbing treatment (rubbing-treated alignment layer) is preferable from the viewpoint of easy control of a pretilt angle of the alignment layer, but from the viewpoint of uniformity of alignment which is important in the present invention, an alignment layer formed from a composition containing a radically polymerizable compound (for example, a compound containing a group having an ethylenically unsaturated double bond) is more preferable, and a photo-alignment layer formed by light irradiation is still more preferable.

Furthermore, in a case where such an alignment layer is used, the laminate of the embodiment of the present invention may have the alignment layer as it is, or may be in a state where the alignment layer is peeled.

<Rubbing-Treated Alignment Layer>

A polymer material used for an alignment layer formed by a rubbing treatment is described in many documents, and many commercially available products thereof can be obtained. In the present invention, a polyvinyl alcohol or a polyimide, and derivatives thereof are preferably used. With regard to the alignment layer, reference can be made to the descriptions on page 43, line 24 to page 49, line 8 of WO2001/88574A1. A thickness of the alignment layer is preferably 0.01 to 10 μm, and more preferably 0.01 to 2 μm.

<Photo-Alignment Layer>

The photo-alignment layer which may be contained in the laminate of the embodiment of the present invention is not particularly limited, and a known photo-alignment layer can be used.

A material for forming the photo-alignment layer is not particularly limited, but a compound having a photoaligned group is usually used. The compound may be a polymer having a repeating unit including a photoaligned group.

The photoaligned group is a functional group capable of imparting anisotropy to the film upon irradiation with light. More specifically, the photoaligned group is a group in which the molecular structure in the group can be changed upon irradiation with light (for example, linearly polarized light). Typically, the photoaligned group refers to a group which causes at least one photoreaction selected from a photoisomerization reaction, a photodimerization reaction, or a photodegradation reaction by irradiation with light (for example, linearly polarized light).

Among these photoaligned groups, the group that causes a photoisomerization reaction (a group having a photoisomerization structure) and the group that causes a photodimerization reaction (a group having a photodimerization structure) are preferable, and the group that causes photodimerization reaction is more preferable.

The photoisomerization reaction refers to a reaction that causes stereoisomerization or structural isomerization by the action of light. As a substance that causes such a photoisomerization reaction, for example, a substance having an azobenzene structure (K. Ichimura et al., Mol. Cryst. Liq. Cryst., 298, page 221 (1997)), a substance having a hydrazono-β-keto ester structure (S. Yamamura et al., Liquid Crystals, vol. 13, No. 2, page 189 (1993)), a substance having a stilbene structure (J. G. Victor and J. M. Torkelson, Macromolecules, 20, page 2241 (1987)), a group having a cinnamic acid (cinnamoyl) structure (skeleton), a substance having a spiropyran structure (K. Ichimura et al., Chemistry Letters, page 1063 (1992); K. Ichimura et al., Thin Solid Films, vol. 235, page 101 (1993)), and the like are known.

As the group that causes a photoisomerization reaction, a group including a C═C bond or an N═N bond, which causes a photoisomerization reaction, is preferable, and examples of such a group include a group having an azobenzene structure (skeleton), a group having a hydrazone-β-keto ester structure (skeleton), a group having a stilbene structure (skeleton), a group having a cinnamic acid (cinnamoyl) structure (skeleton), and a group having a spiropyran structure (skeleton). Among these groups, the group having a cinnamoyl structure and the group having a coumarin structure are preferable, and the group having a cinnamoyl structure is more preferable.

The photodimerization reaction refers to a reaction in which an addition reaction occurs between two groups by the action of light, whereby a ring structure is typically formed. As a substance that causes such photodimerization, a substance having a cinnamic acid structure (M. Schadt et al., J. Appl. Phys., Vol. 31, No. 7, page 2155 (1992)), a substance having a coumarin structure (M. Schadt et al., Nature., Vol. 381, page 212 (1996)), a substance having a chalcone structure (Toshihiro Ogawa et al., Pre-Text of Liquid Crystal Discussion Meeting, 2AB03 (1997)), a substance having a benzophenone structure (Y. K. Jang et al., SID Int. Symposium Digest, P-53 (1997)), and the like are known.

Examples of the group that causes a photodimerization reaction include a group having a cinnamic acid (cinnamoyl) structure (skeleton), a group having a coumarin structure (skeleton), a group having a chalcone structure (skeleton), a group having a benzophenone structure (skeleton), and a group having an anthracene structure (skeleton). Among these groups, the group having a cinnamoyl structure and the group having a coumarin structure are preferable, and the group having a cinnamoyl structure is more preferable.

Moreover, it is preferable that the compound having a photoaligned group further has a crosslinkable group.

As the crosslinkable group, a thermally crosslinkable group that causes a curing reaction by the action of heat, or a photocrosslinkable group that causes a curing reaction by the action of light is preferable, and the crosslinkable group may be a crosslinkable group having both the thermally crosslinkable group and the photocrosslinkable group.

Examples of the crosslinkable group include at least one selected from the group consisting of an epoxy group, an oxetanyl group, a group represented by —NH—CH₂—O—R (R represents a hydrogen atom or an alkyl group having 1 to 20 carbon atoms), a radically polymerizable group (group having an ethylenically unsaturated double bond, and a blocked isocyanate group. Among these, the epoxy group, the oxetanyl group, and the group having an ethylenically unsaturated double bond are preferable.

Furthermore, the 3-membered cyclic ether group is also referred to as an epoxy group, and the 4-membered cyclic ether group is also referred to as an oxetanyl group.

In addition, specific examples of the radically polymerizable group (group having an ethylenically unsaturated double bond) include a vinyl group, an allyl group, a styryl group, an acryloyl group, and a methacryloyl group, and the acryloyl group or the methacryloyl group is preferable.

As one of the suitable aspects of the photo-alignment layer, a photo-alignment layer formed with the composition for forming a photo-alignment layer, including a polymer A having a repeating unit al including a cinnamate group and a low-molecular-weight compound B having a cinnamate group and having a lower molecular weight than that of the polymer A, may be mentioned.

Here, in the present specification, the cinnamate group is referred to as a group having a cinnamic acid structure including cinnamic acid or a derivative thereof as a basic skeleton, in which the group is represented by Formula (I) or Formula (II).

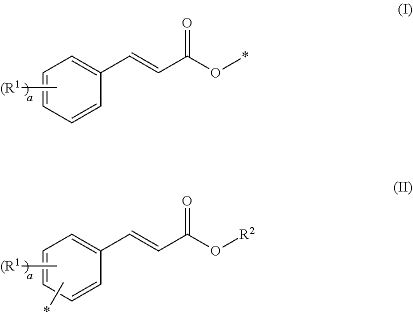

In Formula, R¹ represents a hydrogen atom or a monovalent organic group, and R² represents a monovalent organic group. In Formula (I), a represents an integer of 0 to 5, and in Formula (II), a represents 0 to 4. In a case where a is 2 or more, a plurality of R¹'s may be the same as or different from each other. * represents a bond.

The polymer A is not particularly limited as long as it is a polymer having a repeating unit al including a cinnamate group, and a polymer known in the related art can be used.

A weight-average molecular weight of the polymer A is preferably 1,000 to 500,000, more preferably 2,000 to 300,000, and still more preferably 3,000 to 200,000.

Here, the weight-average molecular weight is defined as a value expressed in terms of polystyrene (PS), measured by means of gel permeation chromatography (GPC), and the measurement by means of GPC in the present invention can be made using HLC-8220 GPC (manufactured by Tosoh Corporation), and TSKgel Super HZM-H, HZ4000, and HZ2000 as columns.

Examples of the repeating unit al including a cinnamate group, contained in the polymer A, include repeating units represented by Formulae (A1) to (A4).

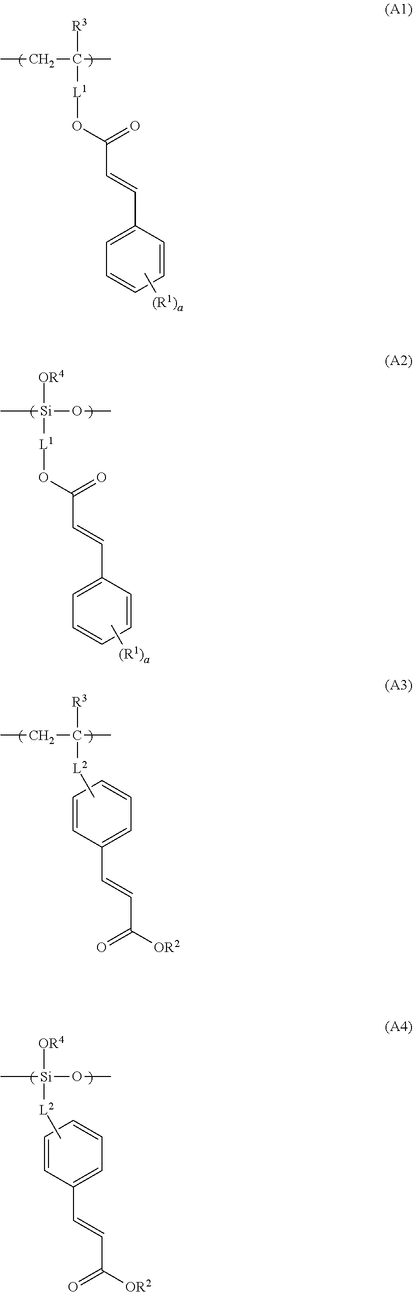

Here, in Formulae (A1) and (A3), R³ represents a hydrogen atom or a methyl group, and in Formulae (A2) and (A4), R⁴ represents an alkyl group having 1 to 6 carbon atoms.

In Formulae (A1) and (A2), L¹ represents a single bond or a divalent linking group, a represents an integer from 0 to 5, and R¹ represents a hydrogen atom or a monovalent organic group.

In Formulae (A3) and (A4), L² represents a divalent linking group and R² represents a monovalent organic group.

In addition, specific examples of L¹ include —CO—O-Ph-, —CO—O-Ph-Ph-, —CO—O—(CH₂)ₙ—, —CO—O—(CH₂)ₙ-Cy-, and —(CH₂)ₙ-Cy-. Here, Ph represents a divalent benzene ring which may have a substituent (for example, a phenylene group), Cy represents a divalent cyclohexane ring which may have a substituent (for example, a cyclohexane-1,4-diyl group), and n represents an integer of 1 to 4.

In addition, specific examples of L² include —O—CO— and —O—CO—(CH₂)ₘ—O—. Here, m represents an integer of 1 to 6.

In addition, examples of the monovalent organic group of R¹ include a chain or cyclic alkyl group having 1 to 20 carbon atoms, an alkoxy group having 1 to 20 carbon atoms, and an aryl group having 6 to 20 carbon atoms, which may have a substituent.

Furthermore, examples of the monovalent organic group of R² include a chain or cyclic alkyl group having 1 to 20 carbon atoms, and an aryl group having 6 to 20 carbon atoms, which may have a substituent.

Moreover, a is preferably 1 and R¹ is preferably present in the para position.

In addition, examples of the substituent which may be contained in Ph, Cy, and the aryl group, each mentioned above, include an alkyl group, an alkoxy group, a hydroxy group, a carboxy group, and an amino group.

From the viewpoints that the alignment of the light absorption anisotropic layer is further improved and the adhesiveness of the light absorption anisotropic layer is further improved, it is preferable that the polymer A further has a repeating unit a2 including a crosslinkable group.

The definition and suitable aspects of the crosslinkable group are as described above.

Among those, as the repeating unit a2 including a crosslinkable group, a repeating unit having an epoxy group, an oxetanyl group, or a group having an ethylenically unsaturated double bond is preferable.

The following repeating units can be exemplified as preferred specific examples of the repeating unit having an epoxy group, an oxetanyl group, or a group having an ethylenically unsaturated double bond. Furthermore, R³ and R⁴ have the same definitions as R³ and R⁴, respectively, in Formulae (A1) and (A1).

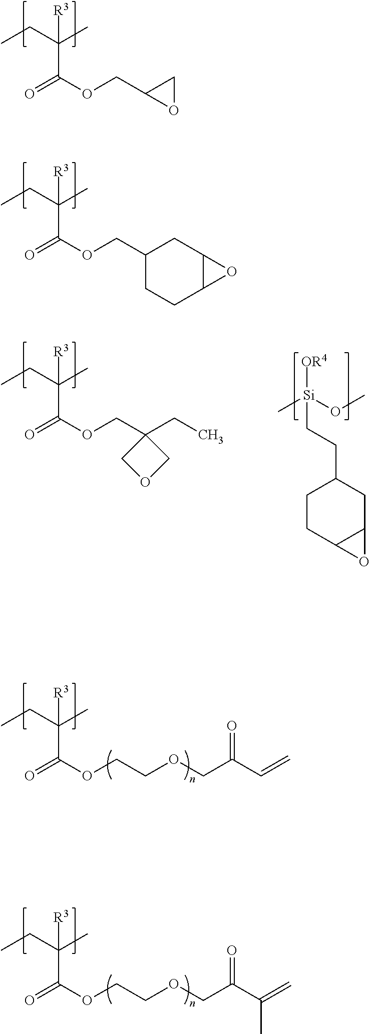

The polymer A may have another repeating unit other than the repeating unit a1 and the repeating unit a2, each mentioned above.

Examples of a monomer forming such another repeating unit include an acrylic acid ester compound, a methacrylic acid ester compound, a maleimide compound, an acrylamide compound, acrylonitrile, maleic acid anhydride, a styrene compound, and a vinyl compound.

A content of the polymer A in the composition for forming a photo-alignment layer is preferably 0.1 to 50 parts by mass, and more preferably 0.5 to 10 parts by mass with respect to 100 parts by mass of the solvent in a case where an organic solvent which will be described later is included.

The low-molecular-weight compound B is a compound having a cinnamate group and having a lower molecular weight than the polymer A. By using the low-molecular-weight compound B, the alignment of the produced photo-alignment layer is better.

For a reason that the alignment of the photo-alignment layer is further improved, a molecular weight of the low-molecular-weight compound B is preferably 200 to 500, and more preferably 200 to 400.

Examples of the low-molecular-weight compound B include a compound represented by Formula (B1).

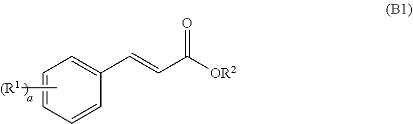

In Formula (B1), a represents an integer from 0 to 5, R¹ represents a hydrogen atom or a monovalent organic group, and R² represents a monovalent organic group. In a case where a is 2 or more, a plurality of R¹'s may be the same as or different from each other.

In addition, examples of the monovalent organic group of R¹ include a chain or cyclic alkyl group having 1 to 20 carbon atoms, an alkoxy group having 1 to 20 carbon atoms, and an aryl group having 6 to 20 carbon atoms, which may have a substituent, and among these, the alkoxy group having 1 to 20 carbon atoms is preferable, an alkoxy group having 1 to 6 carbon atoms is more preferable, and a methoxy group or an ethoxy group is still more preferable.

Furthermore, examples of the monovalent organic group of R² include a chain or cyclic alkyl group having 1 to 20 carbon atoms and an aryl group having 6 to 20 carbon atoms, which may have a substituent, and among these, the chain alkyl group having 1 to 20 carbon atoms is preferable, and a branched alkyl group having 1 to 10 carbon atoms is more preferable.

Moreover, a is preferably 1 and R¹ is preferably present in the para position.

In addition, examples of the substituent which may be contained in the above-mentioned aryl group include an alkyl group, an alkoxy group, a hydroxy group, a carboxy group, and an amino group.

A content of the low-molecular-weight compound B in the composition for forming a photo-alignment layer is preferably 10% to 500% by mass, and more preferably 30% to 300% by mass with respect to a mass of the constitutional unit al of the polymer A.

For a reason that the alignment is further improved, the composition for forming a photo-alignment layer preferably includes a crosslinking agent C having a crosslinkable group, in addition to the polymer A having a constitutional unit a2 including a crosslinkable group.

A molecular weight of the crosslinking agent C is preferably 1,000 or less, and more preferably 100 to 500.

Examples of the crosslinking agent C include a compound having two or more epoxy groups or oxetanyl groups in the molecule, a blocked isocyanate compound (a compound having a protected isocyanato group), and an alkoxymethyl group-containing compound.

Among those, the compound having two or more epoxy groups or oxetanyl groups in the molecule, or the blocked isocyanate compound is preferable.

In a ease where the composition for forming a photo-alignment layer includes the crosslinking agent C, a content of the crosslinking agent C is preferably 1 to 1,000 parts by mass, and more preferably 10 to 500 parts by mass with respect to 100 parts by mass of the constitutional unit a1 of the polymer A.

From the viewpoint of workability for producing a photo-alignment layer, it is preferable that the composition for forming a photo-alignment layer includes a solvent. Examples of the solvent include water and an organic solvent.

Specific examples of the organic solvent include ketones (for example, acetone, 2-butanone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide). These solvents may be used alone or in combination of two or more kinds thereof.

The composition for forming a photo-alignment layer may include components other than the above-mentioned components, and examples of the components include a crosslinking catalyst, an adhesion improver, a leveling agent, a surfactant, and a plasticizer.

<Method for Forming Photo-Alignment Layer>

A method for forming the photo-alignment layer is not particularly limited, and for example, the photo-alignment layer can be produced by an applying step of applying the above-mentioned composition for forming the photo-alignment layer onto a surface of a support, and a light irradiating step of irradiating the coating film of the composition for forming a photo-alignment layer with polarized light or with non-polarized light from an oblique direction with respect to the coating film surface.

[λ/4 Plate]

In a case where the above-mentioned light absorption anisotropic layer functions as a circularly polarizing plate, it is preferable that the laminate of the embodiment of the present invention has a λ/4 plate.

Here, the “λ/4 plate” is a plate having a λ/4 function, specifically, a plate having a function of converting a linearly polarized light at a certain specific wavelength into a circularly polarized light (or converting a circularly polarized light to a linearly polarized light).

Specific examples of an aspect in which the λ/4 plate has a mono-layer structure include a phase difference film provided with an optically anisotropic layer which exhibits refractive index anisotropy in liquid crystal alignment and has a λ/4 function.

In addition, specific examples of an aspect in which the λ/4 plate has a multi-layer structure include a wideband λ/4 plate formed by laminating a λ/4 plate and a λ/2 plate, an ultrawideband λ/4 plate in which a λ/2 plate is further laminated on the wideband λ/4 plate, and a wideband λ/4 plate in which a phase difference plate using a liquid crystal having a reverse dispersion wavelength characteristic, a twist alignment layer, a positive-C plate, and the like.

The λ/4 plate and the light absorption anisotropic layer may be laminated, or another layer may be provided between the λ/4 plate and the liquid crystal film. Examples of such a layer include an adhesive layer for ensuring adhesiveness.

[Barrier Layer]

The laminate of the embodiment of the present invention preferably has a barrier layer together with a light absorption anisotropic layer.

Here, the barrier layer is also called a gas shielding layer (oxygen shielding layer), and has a function of protecting the polarizing element of the present invention from a gas such as oxygen in the air, moisture, compounds included in an adjacent layer, and the like.

With regard to the barrier layer, reference can be made to, for example, the descriptions in paragraphs [0014] to [0054] of JP2014-159124A, paragraphs [0042] to [0075] of JP2017-121721A, paragraphs [0045] to [0054] of JP2017-115076A, paragraphs [0010] to of JP2012-213938A, or paragraphs [0021] to [0031] of JP2005-169994A.

[Cured Layer]

In the laminate of the embodiment of the present invention, in a case where the above-mentioned light absorption anisotropic layer has a dichroic substance and is used for the purpose of antireflection as a circularly polarizing plate, internal reflection due to a high refractive index of the light absorption anisotropic layer may be problematic. In that case, a cured layer which will be described below is preferably present.

The cured layer is a layer arranged so as to be in contact with the light absorption anisotropic layer, is formed from a composition containing a compound having a crosslinkable group, and has an in-plane average refractive index from 1.55 to 1.70 at a wavelength of 550 nm. The cured layer is preferably a refractive index-adjusting layer for performing a so-called index matching.

An in-plane average refractive index of the refractive index-adjusting layer may be in the range, but is preferably 1.58 to 1.70 and more preferably 1.60 to 1.70.

A thickness of the refractive index-adjusting layer is not particularly limited, but is preferably 0.01 to 2.00 μm, more preferably 0.01 to 0.80 μm, and still more preferably 0.01 to 0.15 μm from the viewpoint of reduction in the thickness.

A type of a component constituting the refractive index-adjusting layer is not particularly limited as long as the component contains a compound having a crosslinkable group. The hardness in the layer can be ensured by the presence of the crosslinkable group. A compound cured by light or heat, for example, a polymerizable compound having a (meth)acryloyl group or an epoxy group is preferable. Moreover, from the viewpoint that a high in-plane average refractive index can be obtained, a polymerizable liquid crystalline compound is also preferable. In addition, the polymerizable liquid crystalline compound can control the anisotropy of the refractive index in the plane, and thus has a high potential for optimizing the refractive index with the light absorption anisotropic layer having the refractive index anisotropy in the plane.

The refractive index-adjusting layer may include particles together with the compound having a crosslinkable group. Examples of the particles include organic particles, inorganic particles, and organic-inorganic composite particles including an organic component and an inorganic component.

Examples of the organic particles include styrene resin particles, styrene-divinylbenzene copolymer particles, acrylic resin particles, methacrylic resin particles, styrene-acryl copolymer particles, styrene-methacryl copolymer particles, melamine resin particles, and resin particles including two or more kinds thereof.

Examples of a component constituting the inorganic particles include a metal oxide, a metal nitride, a metal oxynitride, and a metal simple substance. Examples of a metallic atom included in the metal oxide, metal nitride, metal oxynitride, and metal simple substance include a titanium atom, a silicon atom, an aluminum atom, a cobalt atom, and a zirconium atom. Specific examples of the inorganic particles include inorganic oxide particles such as alumina particles, hydrated alumina particles, silica particles, zirconia particles, and a clay mineral (for example, smectite). From the viewpoint that a high refractive index can be obtained, zirconia particles are preferable.

An average particle diameter of the particles is preferably 1 to 300 nm, and more preferably 10 to 200 nm.

In a case where the average particle diameter is in the range, a cured product (transparent resin layer) having excellent dispersibility of the particles and superior high-temperature durability, moisture-heat resistance, and transparency can be obtained.

Here, the average particle diameter of the particles can be obtained from a photograph obtained by observation with a transmission electron microscope (TEM) or a scanning electron microscope (SEM). Specifically, the projected area of the particle is obtained, and the corresponding circle-equivalent diameter (a diameter of a circle) is taken as the average particle diameter of the particles. Moreover, the average particle diameter in the present invention is an arithmetic mean value of circle-equivalent diameters obtained for 100 particles. The particles may have any shape such as a spherical shape, a needle shape, a fiber (fiber shape), a columnar shape, and a plate shape.

A content of the particles in the refractive index-adjusting layer is not particularly limited, but is preferably 1% to 50% by mass and more preferably 1% to 30% by mass, with respect to the total mass of the refractive index-adjusting layer, from the viewpoint that the in-plane average refractive index of the refractive index-adjusting layer is easily adjusted.

A method for forming the refractive index-adjusting layer is not particularly limited, but examples thereof include a method in which a composition for forming a refractive index-adjusting layer is applied onto a polarizer, and the coating film is subjected to a curing treatment, as necessary.

The composition for forming a refractive index-adjusting layer includes components which can constitute the refractive index-adjusting layer, and examples of the components include a resin, a monomer, and particles. Examples of the resin and the particles are as described above.

Examples of the monomer include a photocurable compound and a thermosetting compound (for example, a thermosetting resin). As the monomer, a monofunctional polymerizable compound including one polymerizable group in one molecule, and a polyfunctional polymerizable compound including the same or different two or more polymerizable groups in one molecule are preferable. The polymerizable compound may be a monomer or a multimer such as an oligomer or a prepolymer.

Examples of the polymerizable group include a radically polymerizable group and a cationically polymerizable group, and a radically polymerizable group is preferable. Examples of the radically polymerizable group include an ethylenically unsaturated bond group. Examples of the canonically polymerizable group include an epoxy group and an oxetane group.

The composition for forming a refractive index-adjusting layer may include at least one of an interface modifier, a polymerization initiator, or a solvent. Examples of these components include the compounds exemplified as the components which may be included in the liquid crystalline composition.

A method for applying the composition for forming a refractive index-adjusting layer is not particularly limited, and examples thereof include a method for applying the above-mentioned liquid crystalline composition.

After the composition for forming a refractive index-adjusting layer is applied, as necessary, the coating film may be subjected to a drying treatment.

In addition, in a ease where the composition for forming a refractive index-adjusting layer includes a curable compound such as a monomer, after the composition for forming a refractive index-adjusting layer is applied, the coating film may be subjected to a curing treatment.

Examples of the curing treatment include a photocuring treatment and a thermosetting treatment, and optimal conditions are selected according to the material used.

In a case where a polymerizable liquid crystalline compound is used, the compound is not particularly limited.

In general, the liquid crystalline compound can be classified into a rod-like type and a disk-like type according to the shape thereof. Furthermore, each liquid crystalline compound is either of a low-molecular-weight type or of a high-molecular-weight type. In general, the high-molecular-weight type compound indicates a compound having a degree of polymerization of 100 or more (Polymer Physics⋅Phase Transition Dynamics, written by Masao DOI, page 2, Iwanami Shoten, Publishers, 1992).

In the present invention, any liquid crystalline compound can be used, but a rod-like liquid crystalline compound (hereinafter also simply referred to as “CLC”) or a discotic liquid crystalline compound (hereinafter also simply referred to as “DLC”) is preferably used, and the rod-like liquid crystalline compound is more preferably used. Moreover, two or more kinds of rod-like liquid crystalline compounds, two or more kinds of disk-like liquid crystalline compounds, or a mixture of the rod-like liquid crystalline compound and the disk-like liquid crystalline compound may be used.

In the present invention, it is necessary to use a liquid crystalline compound having a polymerizable group for immobilization of the above-mentioned liquid crystalline compound, and it is more preferable that the liquid crystalline compound has two or more polymerizable groups in the molecule. Moreover, in a case where the liquid crystalline compound is a mixture of two or more kinds thereof, it is preferable that at least one kind of the liquid crystalline compounds has two or more polymerizable groups in one molecule. Furthermore, after the liquid crystalline compound is immobilized by polymerization, it is no longer necessary to exhibit liquid crystallinity.

In addition, a type of the polymerizable group is not particularly limited, and the polymerizable group is preferably a functional group capable of an addition polymerization reaction, and is also preferably a polymerizable ethylenically unsaturated group or a ring polymerizable group. More specifically, preferred examples of the polymerizable group include a (meth)acryloyl group, a vinyl group, a styryl group, and an allyl group, and the meth)acryloyl group is more preferable. Moreover, the (meth)acryloyl group is a notation meaning a methacryloyl group or an acryloyl group.

As the rod-like liquid crystalline compound, for example, the compounds described in claim 1 of JP1999-513019A (JP-H11-513019A) or paragraphs [0026] to [0098] of JP2005-289980A can be preferably used, and as the discotic liquid crystalline compound, for example, the compounds described in paragraphs [0020] to [0067] of JP2007-108732A or paragraphs [0013] to [0108] of JP2010-244038A can be preferably used, but the present invention is not limited to these examples.

<Other Components>

Specific examples of other components included in the composition for forming a refractive index-adjusting layer include the polymerization initiator, the surfactant, and the solvent, each described for the above-mentioned composition containing a dichroic azo coloring agent compound (composition for forming a light absorption anisotropic layer).

<Formation Method>

A method for forming a light absorption anisotropic layer using the above-mentioned composition for forming a light absorption anisotropic layer is not particularly limited, and examples thereof include a method including a step (hereinafter also referred to as a “coating film forming step”) of applying the above-mentioned composition for forming a light absorption anisotropic layer onto the above-mentioned alignment film or the above-mentioned light absorption anisotropic layer according to the layer configuration to form a coating film, and a step (hereinafter also referred to as an “aligning step”) of aligning liquid crystalline components included in the coating film, in this order.

Here, examples of the coating film forming step and the aligning step include the same steps as those described for the above-mentioned method for forming a light absorption anisotropic layer.

[Adhesive Layer]

The laminate of the embodiment of the present invention may have an adhesive layer between the resin substrate and the light absorption anisotropic layer, as shown in the layer configuration which will be described later.

Here, the adhesive included in the adhesive layer is not particularly limited as long as it exhibits adhesiveness by drying or reaction after affixing.

For example, a polyvinyl alcohol-based adhesive (PVA-based adhesive) exhibits adhesiveness by being dried, and thus enables the adhesion between materials.

In addition, specific examples of a curable adhesive which exhibits adhesiveness by being reacted include an active energy ray curing type adhesive such as a (meth)acrylate-based adhesive, and a cationic polymerization curing type adhesive.

Examples of a curable component in the (meth)acrylate-based adhesive include a compound having a (meth)acryloyl group and a compound having a vinyl group.

Furthermore, a compound having an epoxy group or an oxetanyl group can also be used as the cationic polymerization-curable adhesive. The compound having an epoxy group is not particularly limited as long as it has at least two epoxy groups in the molecule, and various curable epoxy compounds generally known can be used. Preferred examples of the epoxy compound include a compound (aromatic epoxy compound) having at least two epoxy groups and at least one aromatic ring in the molecule and a compound (alicyclic epoxy compound) having at least two epoxy groups in the molecule, at least one of which is formed between two adjacent carbon atoms constituting an alicyclic ring.

As the adhesive in the present invention, an ultraviolet curable adhesive which is cured by ultraviolet irradiation is preferably used from the viewpoint of heat deformation resistance. In addition, in a case where the light absorption anisotropic layer is affixed to the resin substrate, a (meth)acrylate-based adhesive is preferable from the viewpoint of the adhesiveness to the resin substrate. Among these, the solvent-free (meth)acrylate-based adhesives are the most preferable.

[Layer Configuration]

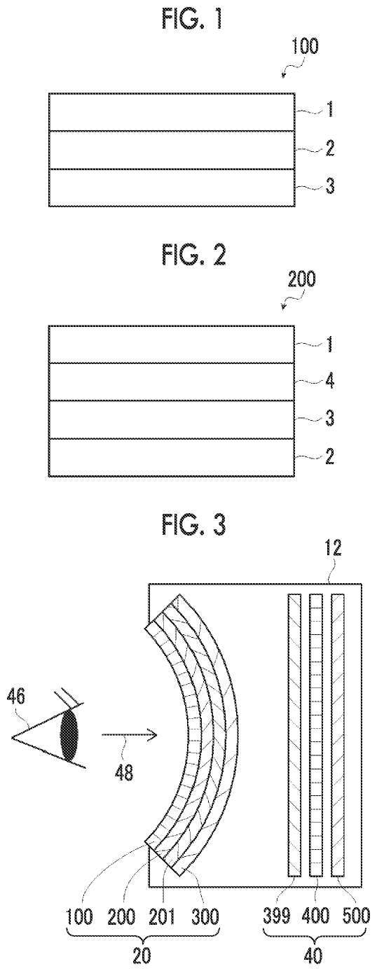

The laminate of the embodiment of the present invention preferably has a layer configuration in which a resin substrate 1 having a tan δ peak temperature of 170° C. or lower, an alignment layer 2, and a light absorption anisotropic layer 3 are arranged in this order, as shown in FIG. 1.

In addition, the laminate of the embodiment of the present invention preferably has a layer configuration in which a resin substrate having a tan δ peak temperature of 170° C. or lower, an adhesive layer, and a light absorption anisotropic layer are arranged in this order.

Furthermore, the laminate of the embodiment of the present invention preferably has a layer configuration in which a resin substrate 1 having a tan δ peak temperature of 170° C. or lower, an adhesive layer 4, a light absorption anisotropic layer 3, and an alignment layer 2 are arranged in this order.

The laminate of the embodiment of the present invention is preferably aged at a high temperature of 140° C. or higher in order to realize a high alignment degree of the dichroic substance in the light absorption anisotropic layer. Therefore, in the step of forming a light absorption anisotropic layer, it is desired to use a resin substrate having a small dimensional change even at a high temperature, for example, a stretched TAC having a tan δ of 180° C. or higher as a support.

On the other hand, from the viewpoint of molding a curved surface on the laminate of the embodiment of the present invention, there is a risk of breakage in the stretched TAC having a tan δ peak temperature of 180° C. or higher in a case of performing thermoforming at a temperature of less than 140° C., and the degree of freedom in a molding process is small.

Therefore, by forming an alignment layer using a resin substrate having a small dimensional change even with high temperature, and then forming a light absorption anisotropic layer, and subsequently, bonding a resin substrate having a tan δ peak temperature of 170° C. or lower thereto by an adhesive, and further, peeling the resin substrate having a small dimensional change even at a high temperature, it is possible to create a laminate in which the resin substrate having a tan δ peak temperature of 170° C. or lower, the adhesive layer, the light absorption anisotropic layer, and the alignment layer are arranged in this order.

[Molding of Curved Surface]

The laminate of the embodiment of the present invention preferably has a curved surface, and more preferably has a three-dimensional curved surface. Incidentally, the three-dimensional curved surface refers to a curved surface which is not a developable surface. A developable surface is a curved surface which can be developed into a flat surface without stretching and contracting, in which the curved surface can be created by bending or cutting a flat surface.

Examples of a method for forming a curved surface on the laminate of the embodiment of the present invention include insert molding as described in JP2004-322501A, and vacuum molding, injection molding, pneumatic molding, vacuum coating molding, in-mold transfer, and mold pressing, as described in WO2010/1867A or JP2012-116094A.

Heating is preferably performed at the time of molding, preferably performed at 80° C. to 170° C., more preferably performed at 100° C. to 150° C., and still more preferably performed at 110° C. to 140° C.

In addition, there is a possibility of, for example, injection molding of a lens and the like after molding the laminate, and in this case, the laminate is required to have resistance to a heating process of several minutes or more.

[Surface Irregularities]

The laminate of the embodiment of the present invention preferably has a smooth surface. In particular, in a case where the laminate of the embodiment of the present invention is applied to a lens or the like, slight surface irregularities may lead to distortion of an image due to the effect of image enlargement of the lens, and therefore, it is desired that the surface has no irregularities. Specifically, an average arithmetic roughness Ra of the surface is preferably 50 nm or less, more preferably 30 nm or less, still more preferably 10 nm or less, and most preferably 5 nm or less. In addition, a height difference of the surface irregularities in the range of 1 square millimeter is preferably 100 nm or less, more preferably 50 nm or less, and still more preferably 20 nm or less on a surface of the laminate.

In order to realize the smoothness, it is preferable that the surface of the light absorption anisotropic layer of the present invention is also smooth. Specifically, an average arithmetic roughness Ra of the surface is preferably 50 nm or less, more preferably 30 nm or less, still more preferably 10 nm or less, and most preferably 5 nm or less. In addition, a height difference of the surface irregularities in the range of 1 square millimeter is preferably 100 nm or less, more preferably 50 nm or less, and still more preferably 20 nm or less on a surface of the laminate.

The surface irregularities and the average arithmetic roughness can be measured using a roughness meter or an interferometer. For example, the surface irregularities and the average arithmetic roughness can be measured using an interferometer “vertscan” manufactured by Ryoka System Co., Ltd.

[Use]

The laminate of the embodiment of the present invention can be used as a polarizing element (polarizing plate) for various articles having a curved surface. For example, the laminate can be used for an in-vehicle display having a curved surface, a lens for a sunglass, a lens for goggles for an image display device, and the like. With regard to the polarizing plate or the circularly polarizing plate in the present embodiment, the polarizing plate or the circularly polarizing plate can be affixed onto a curved surface or integrally molded with a resin, which therefore contributes to an improvement of the design.

The polarizing plate or the circularly polarizing plate is also preferably used for the purpose of suppressing stray light in in-vehicle display optical systems such as a head-up display, an optical system such as an augmented reality (AR) eyeglass and a virtual reality (VR) eyeglass, optical sensors such as light detection and ranging (LiDAR), a face recognition system, and a polarization imaging, and the like. In addition, the polarizing plate or the circularly polarizing plate is also preferably used in combination with a phase difference plate for the purpose of antireflection.

[Optical Device]

The optical device of an embodiment of the present invention is an optical device having a curved surface, in which the laminate of the embodiment of the present invention having a curved surface is arranged along the curved surface of the optical device.

Examples of such an optical device include a portable electronic apparatus such as a mobile phone, a smartphone, and a tablet PC; and an in-vehicle electronic apparatus such as an infrared sensor, a near-infrared sensor, a millimeter-wave radar, an LED spot lighting device, a near-infrared LED lighting device, a mirror monitor, a meter panel, a head-mounted display, and a head-up display.

[Display Device]

The display device of an embodiment of the present invention is a display device having a plurality of members having a curved surface, in which the laminate of the embodiment of the present invention having a curved surface is arranged along a further visible side of the curved surface of a member existing on the most visible side among the members having a curved surface.

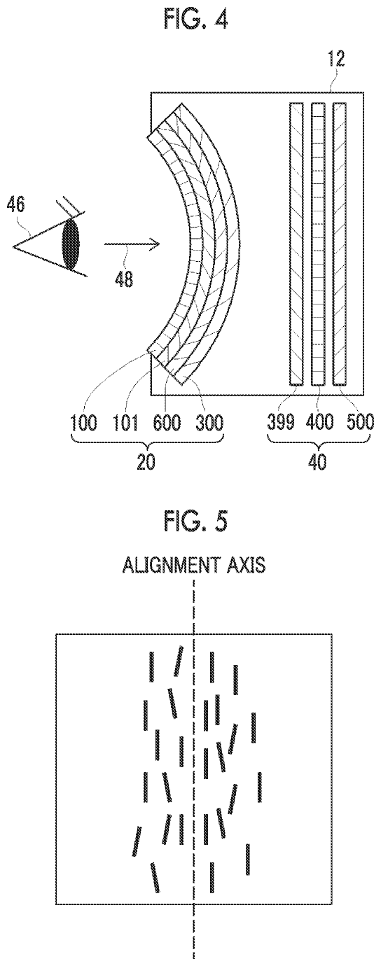

FIGS. 3 and 4 are cross-sectional side views of a head-mounted display which is an example of the display device of the embodiment of the present invention.

Specifically, FIGS. 3 and 4 show a cross-sectional side view of a head-mounted display 10, showing how an optical system 20 and a display system 40 can be supported by a head-mounted support structure such as a housing 12 of the head-mounted display 10.

The housing 12 may have a shape of a pair of eyeglass frames (for example, the head-mounted display 10 may resemble eyeglasses) or a shape of a helmet (for example, the eyeglasses 10 may form a helmet-mounted display), may have a shape of goggles, and may have any other suitable housing shape that allows the housing 12 to be worn on the user's head.

In addition, in a case where a user is visually recognizing the system 20 and the display system 40 in the direction 48, a configuration in which the housing 12 supports the optical system 20 and the display system 40 in front of the user's eye (for example, an eye 46) is preferable.

The display system 40 shown in FIGS. 3 and 4 can include an image source such as an image display panel 500. An image display panel 500 can include a two-dimensional array of pixels P that emit image light (for example, an organic light emitting diode pixel, a light emitting diode pixel formed from a semiconductor die, a liquid crystal display pixel having a backlight, and a liquid crystal pixel on silicon with a front light, and the like).

The polarizer element such as a linear polarizer B400 may be arranged in front of the image display panel 500, or may be laminated on the image display panel 500.

In addition, the display system 40 also includes a wavelength plate such as a second λ/4 plate 399, and can provide circularly polarized image light. The slow axis of the second λ/4 plate 399 can be aligned at 45 degrees with respect to the transmission axis of the linear polarizer B400. The second λ/4 plate 399 can be mounted in front of the linear polarizer B400 (between the linear polarizer B400 and the optical system 20). As desired, the second λ/4 plate 399 can be bonded to the linear polarizer B400 (and the image display panel 500).

The optical system 20 shown in FIGS. 3 and 4 can include a lens element.

In addition, an optical structure such as a partial reflection coating, a wavelength plate, a reflection linear polarizer, a reflection circular polarizer, a linear polarizer, and an antireflection coating can be incorporated into the optical system. For example, the optical system 20 shown in FIG. 3 has a linear polarizer A100, a reflection linear polarizer 200, a first ¼ wavelength plate 201, and a half mirror 300. In addition, the optical system 20 shown in FIG. 4 has a linear polarizer A100, a first ¼ wavelength plate 101, a reflection circular polarizer 600, and a half mirror 300. Incidentally, as the reflection circular polarizer, a cured liquid crystal film in which a rod-like liquid crystal compound is cholesterically aligned is preferably used.

In addition, in the display device of the embodiment of the present invention, the laminate of the embodiment of the present invention having a curved surface can be adopted as the linear polarizer A100 of the optical system 20.

### EXAMPLES

The present invention will be described in more detail with reference to following Examples. The materials, the amounts of materials used, the ratios, the treatment details, the treatment procedure, or the like shown in the following Examples can be appropriately modified without departing from the spirit of the present invention. Therefore, the scope of the present invention will not be restrictively interpreted by the following Examples.

### Creation Example 1

<Manufacture of Cellulose Acylate Film 1>

(Manufacture of Core Layer Cellulose Acylate Dope)

The following composition was introduced into a mixing tank and stirred to dissolve the respective components, thereby preparing a cellulose acetate solution used as a core layer cellulose acylate dope.

Core layer cellulose acylate dope

| | |
|---|---|
| Cellulose acetate with an acetyl substitution degree of 2.88 | 100 parts by mass |
| Polyester compound B described in Examples of JP2015-227955A | 12 parts by mass |
| The following compound F | 2 parts by mass |
| Methylene chloride (first solvent) | 430 parts by mass |
| Methanol (second solvent) | 64 parts by mass |

Compound F

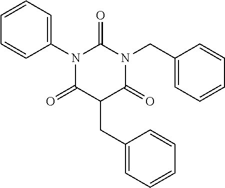 [SMILES: O=C1C(Cc2ccccc2)C(=O)N(c2ccccc2)C(=O)N1Cc1ccccc1]

(Manufacture of Outer Layer Cellulose Acylate Dope)

To 90 parts by mass of the core layer cellulose acylate dope was added 10 parts by mass of the following matting agent solution to prepare a cellulose acetate solution used as an outer layer cellulose acylate dope.

Matting agent solution

| | |
|---|---|
| Silica particles having average particle size | 2 parts by mass |
| of 20 nm (AEROSIL R972, manufactured | |
| by NIPPON AEROSIL CO., LTD.) | |
| Methylene chloride (first solvent) | 76 parts by mass |
| Methanol (second solvent) | 11 parts by mass |
| The core layer cellulose acylate dope | 1 part by mass |

(Manufacture of Cellulose Acylate Film 1)

The core layer cellulose acylate dope and the outer layer cellulose acylate dope were filtered with filter paper having an average pore diameter of 34 μm and a sintered metal filter having an average pore diameter of 10 μm, and then three layers of the core layer cellulose acylate dope and the outer layer cellulose acylate dopes on both sides thereof were cast onto a drum at 20° C. from casting ports at the same time (band casting machine).

Subsequently, the film was peeled in the state where the solvent content reached approximately 20% by mass, the both ends of the film in the width direction were fixed with tenter clips, and the film was dried while being stretched at a stretching ratio of 1.1 times in the cross direction.

Thereafter, the film was transported between rolls in a heat treatment device and further dried to produce an optical film having a thickness of 40 μm, which was used as a cellulose acylate film 1. The in-plane retardation of the obtained cellulose acylate film 1 was 0 nm.

In addition, the tan δ peak temperature of the cellulose acylate film 1 was over 170° C.

<Formation of Photo-Alignment Layer>

A coating liquid PA1 for forming an alignment layer, which will be described later, was continuously applied onto the cellulose acylate film 1 with a wire bar. The support on which the coating film was formed was dried with hot air at 140° C. for 120 seconds, and subsequently, the coating film was irradiated with polarized ultraviolet rays (10 mJ/cm², using an ultra-high-pressure mercury lamp) to form a photo-alignment layer PA1, whereby a TAC film with a photo-alignment layer was obtained.

The film thickness thereof was 0.3 μm.

(Coating liquid PA1 for forming alignment layer)

| | | |
|---|---|---|
| The following polymer PA-1 | 100.00 | parts by mass |
| The following acid generator PAG-1 | 5.00 | parts by mass |
| The following acid generator CPI-110TF | 0.005 | parts by mass |
| Xylene | 1,220.00 | parts by mass |
| Methyl isobutyl ketone | 122.00 | parts by mass |

Polymer PA-1 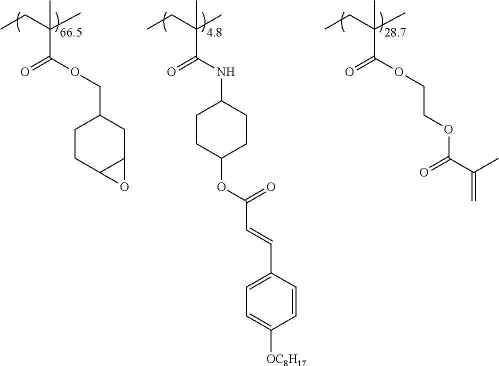
Acid generator PAG-1 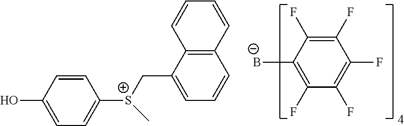
Acid generator CPI-110F

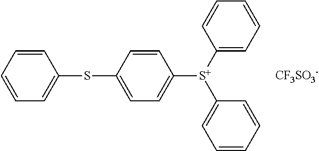

<Formation of Light Absorption Anisotropic Layer P1>

The following composition P1 for forming a light absorption anisotropic layer was continuously applied onto the obtained alignment layer PA1 with a wire bar to form a coating layer P1.

Next, the coating layer P1 was heated at 140° C. for 30 seconds, and the coating layer P1 was cooled to room temperature (23° C.).

Subsequently, the coating layer was heated at 90° C. for 60 seconds and cooled again to room temperature.

Thereafter, the coating layer was irradiated with light for 2 seconds under an irradiation condition of an illuminance of 200 mW/cm², using a LED lamp (center wavelength of 365 nm), to manufacture a light absorption anisotropic layer P1 on the alignment layer PA1. The film thickness thereof was 1.6 μm.

The surface irregularities of the obtained light absorption anisotropic layer P1 had a maximum height difference of 30 nm within a range of 1 square millimeter. In addition, the average arithmetic roughness Ra was 5 nm.

This layer was designated as a laminate 1B.

Composition P1 for forming light absorption anisotropic layer

| The following dichroic substance D-1 | 0.25 | parts by mass |
|---|---|---|
| The following dichroic substance D-2 | 0.36 | parts by mass |
| The following dichroic substance D-3 | 0.59 | parts by mass |
| The following high-molecular-weight liquid crystalline compound P-1 | 2.21 | parts by mass |
| The following low-molecular-weight liquid crystalline compound M-1 | 1.36 | parts by mass |
| Polymerization initiator | | |
| IRGACURE OXE-02 (manufactured by BASF) | 0.200 | parts by mass |
| The following surfactant F-1 | 0.026 | parts by mass |
| Cyclopentanone | 46.00 | parts by mass |
| Tetrahydrofuran | 46.00 | parts by mass |
| Benzyl alcohol | 3.00 | parts by mass |

D-1 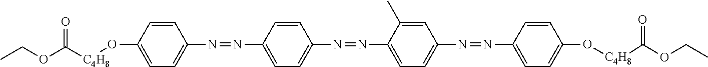
D-2 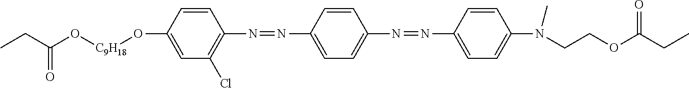
D-3 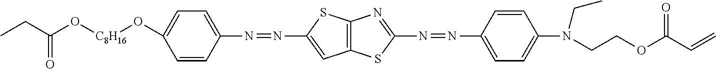
High-molecular-weight liquid crystalline compound P-1 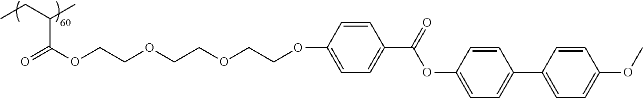 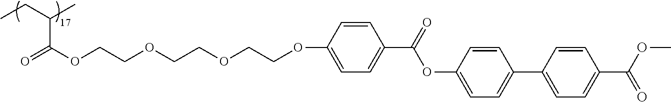 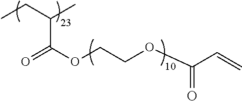
Low-molecular-weight liquid crystalline compound M-1 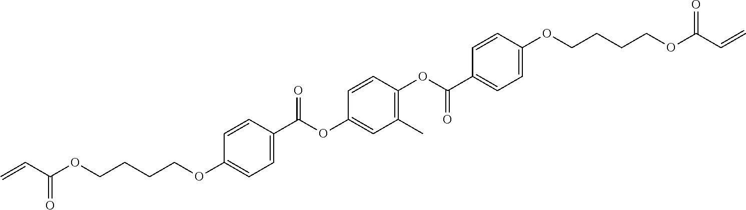 [SMILES: C=CC(=O)OCCCCOc1ccc(C(=O)Oc2ccc(OC(=O)c3ccc(OCCCCOC(=O)C=C)cc3)c(C)c2)cc1]
Surfactant F-1

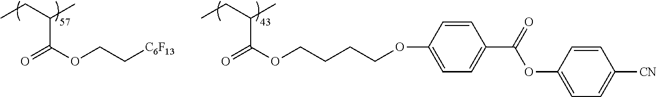

<Manufacture of UV Adhesive>

The following UV adhesive composition was prepared.

UV adhesive composition

| | | |
|---|---|---|
| CEL2021P (manufactured by Daicel Corporation) | 70 | parts by mass |
| 1,4-Butanediol diglycidyl ether | 20 | parts by mass |
| 2-Ethylhexyl glycidyl ether | 10 | parts by mass |
| CPI-100P | 2.25 | parts by mass |

CPI-100P

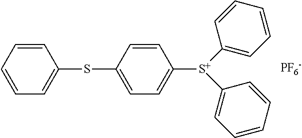

<Creation of Laminate 1>

TECHNOLLOY S001G (methacrylic resin 50 μm thickness, tan δ peak temperature of 121° C., storage elastic modulus at the tan δ peak temperature 17 kPa, available from Sumika Acryl Co., Ltd.) as the resin substrate S1 was bonded onto a surface of the light absorption anisotropic layer of the laminate 1B. Thereafter, only the cellulose acylate film 1 was peeled to create a laminate 1 in which the resin substrate/the adhesive layer/the light absorption anisotropic layer/the alignment layer were arranged in this order.

A thickness of the UV adhesive layer was 2 μm.

### Creation Example 2

A laminate of Creation Example 2 was created in the same manner as in Creation Example 1, except that the composition P1 for forming a light absorption anisotropic layer was replaced by P2 shown below. A film thickness of the light absorption anisotropic layer was changed to 2.7 μm.

The surface irregularities of the light absorption anisotropic layer obtained in Creation Example 2 had a maximum height difference of 22 nm within a range of 1 square millimeter. In addition, the average arithmetic roughness Ra was 4 nm.

Composition P2 for forming light absorption anisotropic layer

| | |
|---|---|
| The dichroic substance D-1 | 0.14 parts by mass |
| The dichroic substance D-2 | 0.21 parts by mass |
| The dichroic substance D-3 | 0.35 parts by mass |
| The high-molecular-weight liquid | 2.97 parts by mass |
| crystalline compound P-1 | |
| The following low-molecular-weight | 1.10 parts by mass |
| liquid crystalline compound M-1 | |
| Polymerization Initiator | 0.200 parts by mass |
| IRGACURE OXE-02 | |
| (manufactured by BASF) | |
| The surfactant F-1 | 0.026 parts by mass |
| Cyclopentanone | 46.00 parts by mass |
| Tetrahydrofuran | 46.00 parts by mass |
| Benzyl alcohol | 3.00 parts by mass |

### Creation Example 3

A laminate of Creation Example 3 was created in the same manner as in Creation Example 1, except that the composition P1 for forming a light absorption anisotropic layer was replaced by P3 shown below.

The surface irregularities of the light absorption anisotropic layer obtained in Creation Example 3 had a maximum height difference of 40 nm within a range of 1 square millimeter. In addition, the average arithmetic roughness Ra was 5 nm.

Composition P3 for forming light absorption anisotropic layer

| The dichroic substance D-1 | 0.25 | parts by mass |
|---|---|---|
| The following dichroic substance D-4 | 0.36 | parts by mass |
| The following dichroic substance D-5 | 0.59 | parts by mass |
| The high-molecular-weight liquid crystalline compound P-1 | 2.21 | parts by mass |
| The low-molecular-weight liquid crystalline compound M-1 | 1.36 | parts by mass |
| Polymerization initiator | | |
| IRGACURE OXE-02 (manufactured by BASF) | 0.200 | parts by mass |
| The surfactant F-1 | 0.026 | parts by mass |
| Cyclopentanone | 46.00 | parts by mass |
| Tetrahydrothran | 46.00 | parts by mass |
| Benzyl alcohol | 3.00 | parts by mass |

D-4 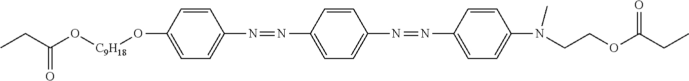
D-5

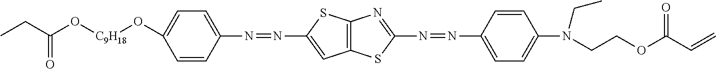

### Creation Example 4

A laminate of Creation Example 4 was created in the same manner as in Creation Example 1, except that the composition P1 for forming a light absorption anisotropic layer was replaced by P4 shown below.

The surface irregularities of the light absorption anisotropic layer obtained in Creation Example 4 had a maximum height difference of 42 nm within a range of 1 square millimeter. In addition, the average arithmetic roughness Ra was 6 nm.

Composition P4 for forming light absorption anisotropic layer

| The following dichroic substance D-6 | 0.25 | parts by mass |
|---|---|---|
| The dichroic substance D-2 | 0.36 | parts by mass |
| The dichroic substance D-3 | 0.59 | parts by mass |
| The high-molecular-weight liquid crystalline compound P-1 | 1.98 | parts by mass |
| The low-molecular-weight liquid crystalline compound M-1 | 1.59 | parts by mass |
| Polymerization initiator | | |
| IRGACURE OKE-02 (manufactured by BASF) | 0.200 | parts by mass |
| The surfactant F-1 | 0.026 | parts by mass |
| Cyclopentanone | 46.00 | parts by mass |
| Tetrahydrofuran | 46.00 | parts by mass |
| Benzyl alcohol | 3.00 | parts by mass |

D-6

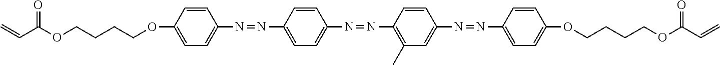 [SMILES: C=CC(=O)OCCCCOc1ccc(N=Nc2ccc(N=Nc3ccc(N=Nc4ccc(OCCCCOC(=O)C=C)cc4)cc3C)cc2)cc1]

### Creation Example 5

A laminate of Creation Example 5 was created in the same manner as in Creation Example 1, except that the composition P1 for forming a light absorption anisotropic layer was replaced by P5 shown below.

The surface irregularities of the light absorption anisotropic layer obtained in Creation Example 5 had a maximum height difference of 45 nm within a range of 1 square millimeter. In addition, the average arithmetic roughness Ra was 5 nm.

Composition P5 for forming light absorption anisotropic layer

| The dichroic substance D-6 | 0.25 | parts by mass |
|---|---|---|
| The dichroic substance D-2 | 0.36 | parts by mass |
| The dichroic substance D-3 | 0.59 | parts by mass |
| The following high-molecular-weight liquid crystalline compound P-2 | 3.12 | parts by mass |
| The low-molecular-weight liquid crystalline compound M-1 | 0.45 | parts by mass |
| Polymerization initiator | | |
| IRGACURE OXE-02 (manufactured by BASF) | 0.200 | parts by mass |
| The surfactant F-1 | 0.026 | parts by mass |
| Cyclopentanone | 46.00 | parts by mass |
| Tetrahydrofuran | 46.00 | parts by mass |
| Benzyl alcohol | 3.00 | parts by mass |

High-molecular-weight liquid crystalline compound P-2

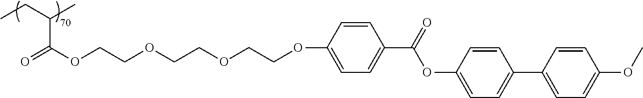

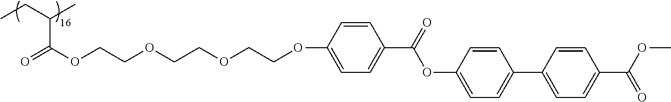

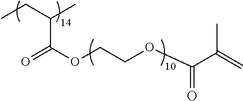

### Creation Example 6

TECHNOLLOY C000 (polycarbonate resin 50 μm thickness, tan δ peak temperature of 156° C., storage elastic modulus at the tan δ peak temperature 31 kPa, available from Sumika Acryl Co., Ltd.) as the resin substrate S2 was bonded onto a surface of the light absorption anisotropic layer of the laminate 1B. Thereafter, only the cellulose acylate film 1 was peeled to create a laminate 6 in which the resin substrate/the adhesive layer/the light absorption anisotropic layer/the alignment layer were arranged in this order. A thickness of the UV adhesive layer was 2 μm.

### Creation Example 7

<Preparation of Composition PA2 for Forming Photo-Alignment Layer>

A composition E1 for forming a photo-alignment layer was prepared with the following composition, dissolved for 1 hour with stirring, and filtered through a 0.45 μm filter.

Composition PA2 for forming photo-alignment layer

| | |
|---|---|
| The following photoactive compound E-4 | 5.0 parts by mass |
| Cyclopentanone | 95.0 parts by mass |

Photoactive compound E-4

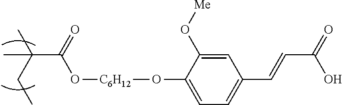

<Preparation of Composition P6 for Forming Light Absorption Anisotropic Layer>

A composition P6 for forming a light absorption anisotropic layer was prepared with the following composition, dissolved by heating at 80° C. for 2 hours with stirring, and filtered through a 0.45 μm filter. A molar cement of the radically polymerizable group is 1.98 mmol/g.

Composition P6 for forming light absorption anisotropic layer

| | |
|---|---|
| The following dichroic coloring agent D-7 | 2.5 parts by mass |
| The following dichroic coloring agent D-8 | 2.5 parts by mass |
| The following dichroic coloring agent D-9 | 2.5 parts by mass |
| The following liquid crystal compound M-2 | 100.0 parts by mass |
| Polymerization initiator | |
| IRGACURE 369E (manufactured by BASF) | 6.0 parts by mass |
| BYK361N (manufactured by BYK Chemie) | 1.2 parts by mass |
| Xylene | 400.0 parts by mass |

Dichroic coloring agent D-7 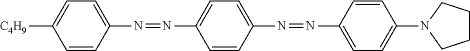
Dichroic coloring agent D-8 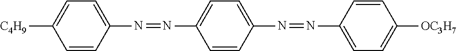
Dichroic coloring agent D-9

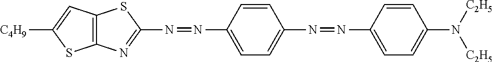

Liquid crystal compound M-2 (Mixed at compound A/compound B=75/25)

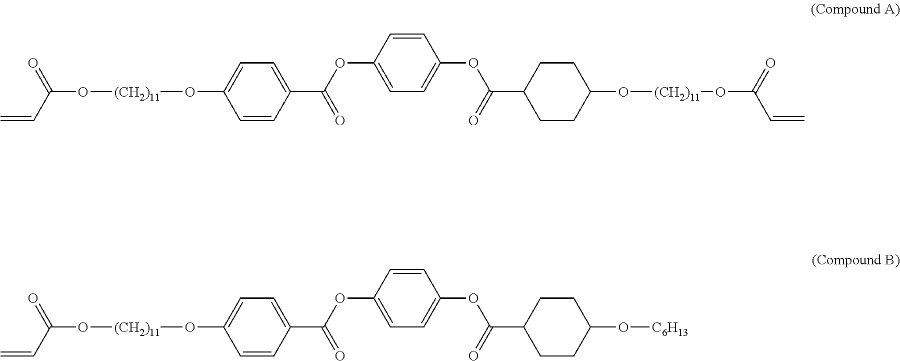

The composition PA2 for forming a photo-alignment layer was applied onto the cellulose triacetate film 1 and dried at 80° C. for 2 minutes. Thereafter, the obtained applied coating film was irradiated with linear polarized ultraviolet rays (100 mJ/cm²) using a polarized ultraviolet exposure device to manufacture a photo-alignment layer PA2.

The composition P6 for forming a light absorption anisotropic layer was applied onto the obtained photo-alignment layer PA2 with a wire bar. Next, the obtained coating film was heated at 110° C. for 180 seconds and cooled to room temperature.

Thereafter, the coating film was irradiated with ultraviolet rays at an exposure amount of 2,000 mJ/cm² using a high-pressure mercury lamp to form a light absorption anisotropic layer P6 having a thickness of 2.0 μm.

Furthermore, it was confirmed that the liquid crystal of the light absorption anisotropic layer was a smectic B phase.

This layer was designated as the laminate 7B.

<Creation of Laminate 7>

TECHNOLLOY S001G (methacrylic resin 50 μm thickness, tan δ peak temperature of 121° C., available from Sumika Acryl Co., Ltd.) as the resin substrate S1 was bonded onto a surface of the light absorption anisotropic layer of the laminate 7B. Thereafter, the cellulose acylate film 1 and the alignment layer were peeled to create a laminate 7 in which the resin substrate/the adhesive layer/the light absorption anisotropic layer were arranged in this order.

A thickness of the UV adhesive layer was 2 μm.

### Creation Example 8

COSMOSHINE A4300 (biaxially stretched PET resin 38 μm thickness, tan δ peak temperature of 111° C., storage elastic modulus at the tan δ peak temperature 1,710 kPa, available from Toyobo Co., Ltd.) as the resin substrate S3 was bonded onto a surface of the light absorption anisotropic layer of the laminate 1B. Thereafter, only the cellulose acylate film 1 was peeled to create a laminate 8 in which the resin substrate/the adhesive layer/the light absorption anisotropic layer/the alignment layer were arranged in this order. A thickness of the UV adhesive layer was 2 μm.

### Creation Example 9

COSMOSHINE SRF (uniaxially stretched PET resin 80 μm thickness, tan δ peak temperature of 119° C., storage elastic modulus at the tan δ peak temperature 2,170 kPa, available from Toyobo Co., Ltd.) as the resin substrate S4 was bonded onto a surface of the light absorption anisotropic layer of the laminate 1B. Thereafter, only the cellulose acylate film 1 was peeled to create a laminate 9 in which the resin substrate/the adhesive layer/the light absorption anisotropic layer/the alignment layer were arranged in this order. A thickness of the UV adhesive layer was 2 μm.

<Evaluation of Alignment Degree>

Each of the light absorption anisotropic layers of Examples and Comparative Examples was set on a sample table in a state where a linear polarizer was inserted into the side of a light source of an optical microscope (manufactured by Nikon Corporation, trade name “ECLIPSE E600 POL”), and a light absorbance of the light absorption anisotropic layer in a wavelength range of 400 to 700 nm was measured using a multi-channel spectrometer (manufactured by Ocean Optics Inc., trade name “QE65000”), and an alignment degree was calculated by the following expression. The results of the laminates 1 to 9 are shown in Table 1 below.

Alignment degree: S=[(Az0/Ay0)−1]/[(Az0/Ay0)+2]

Az0: Light absorbance with respect to polarized light in the direction of an absorption axis of the light absorption anisotropic layer

Ay0: Light absorbance with respect to polarized light in the direction of a polarization axis of the light absorption anisotropic layer

<Biaxial Stretching>

The laminates 1 to 9 were cut into squares of 120 mm×120 mm and subjected to simultaneous biaxial stretching under the following conditions.

Experiment device: Biaxial stretching device EX-10 (Toyo Seiki Seisaku-sho, Ltd.)

Stretching temperature: 125° C.

Stretching speed: 30%/min

Stretching ratio: MD/TD 4%/4%

<Evaluation of Change Rate of Degree of Polarization>

Before and after the simultaneous biaxial stretching, the degree of polarization was evaluated, the change rate of the degree of polarization was evaluated as follows and the results are shown in Table 1.

A: The change rate of the degree of polarization is less than 0.5%

B: The change rate of the degree of polarization is 0.5% or more and less than 1.0%

C: The change rate of the degree of polarization is 1.0% or more

Furthermore, the degree of polarization was measured as follows.

Each of the laminates of Examples and Comparative Examples was set on a sample table in a state where a linear polarizer was inserted into the side of a light source of an optical microscope (manufactured by Nikon Corporation, trade name “ECLIPSE E600 POL”), a light transmittance of each laminate was measured using a multi-channel spectrometer (manufactured by Ocean Optics Inc., trade name “QE65000”), and a degree of polarization was calculated by the following expression.

Degree of polarization: P=√[(Ty0−Tz0)/(Ty0+Tz0)]

Tz0: Light transmittance with respect to polarized light in the absorption axis direction of the laminate

Ty0: Light transmittance with respect to polarized light in the transmission axis direction of the laminate

<Evaluation of Heating Durability>

Laminates 1 to 9 were heated under two conditions of 130° C. and 100° C. for 4 minutes and evaluated as follows from the change rate of the degree of polarization before and after heating. The results are shown in Table 1 below.

AA: The change rate of the degree of polarization is less than 0.3%

A: The change rate of the degree of polarization is 0.3% or more and less than 0.5%

B: The change rate of the degree of polarization is 0.5% or more and less than 1.0%

TABLE 1

| | | | | | | | | Evaluation results | | | |
|---|---|---|---|---|---|---|---|---|---|---|---|
| | | Light absorption | | | | | | | Change rate | Change rate | |
| | Alignment | anisotropic layer | | | Resin substrate | | | Change rate | of degree of | of degree of | |
| | layer | | | Poly- | | tanδ | | of degree | polarization | polarization | |
| | Com- | Com- | | merizable | | peak | Storage | of polarization | after heating | after heating | |
| | position | position | Alignment | group | | temper- | elastic | after biaxial | at 130° C. for | at 100° C. for | |
| | liquid | liquid | degree | mmol/g | | ature | modulus | stretching | 4 minutes | 4 minutes | Note |
| Creation | PA1 | P1 | 0.97 | 1.23 | S1 | 121° C. | 17 kPa | A | A | AA | Inventive |
| Example 1 | | | | | | | | | | | |
| Creation | PA1 | P2 | 0.95 | 1.05 | S1 | 121° C. | 17 kPa | B | A | AA | Inventive |
| Example 2 | | | | | | | | | | | |
| Creation | PA1 | P3 | 0.97 | 1.23 | S1 | 121° C. | 17 kPa | A | A | AA | Inventive |
| Example 3 | | | | | | | | | | | |
| Creation | PA1 | P4 | 0.95 | 1.51 | S1 | 121° C. | 17 kPa | B | AA | AA | Inventive |
| Example 4 | | | | | | | | | | | |
| Creation | PA1 | P5 | 0.97 | 0.76 | S1 | 121° C. | 17 kPa | A | B | A | Inventive |
| Example 5 | | | | | | | | | | | |
| Creation | PA1 | P1 | 0.97 | 1.23 | S2 | 156° C. | 31 kPa | A | A | AA | Inventive |
| Example 6 | | | | | | | | | | | |
| Creation | PA2 | P6 | 0.93 | 1.98 | S1 | 121° C. | 17 kPa | C | AA | AA | Comparative |
| Example 7 | | | | | | | | | | | |
| Creation | PA1 | P1 | 0.97 | 1.23 | S3 | 111° C. | 1710 kPa | A | A | AA | Inventive |
| Example 8 | | | | | | | | | | | |
| Creation | PA1 | P1 | 0.97 | 1.23 | S4 | 121° C. | 2170 kPa | A | A | AA | Inventive |
| Example 9 | | | | | | | | | | | |

Moreover, the laminate of Creation Example 1 could be stretched even at a stretching temperature of 100° C., but the laminate of Creation Example 6 could not be sufficiently stretched at a stretching temperature of 100° C. In a case where the tan δ peak temperature is 130° C. or lower, it is even capable of corresponding to molding at a low temperature.

In addition, the laminates of Creation Examples 8 and 9 were not easily stretched due to misalignment at a chuck site in which the laminates were fixed by performing stretching at 125° C.

Further, a laminate 1B (cellulose acylate film absorption anisotropic layer) was not stretchable due to breakage due to the stretching.

### Creation Example 10

A light absorption anisotropic layer in which a coloring agent was aligned in the vertical direction was created as follows. The light absorption anisotropic layer is capable of absorbing polarized light incident from an oblique direction, and is effective for control of a viewing angle, and the like.

(Manufacture of Transparent Support 1)

A coatings liquid 1 for forming an alignment layer, which will be described later, was continuously applied on a cellulose acylate film 2 (TAC substrate having a thickness of 40 μm; TG40, Fujifilm Corporation) with a wire bar. A support on which the coating film had been formed was dried with warm air at 60° C. for 60 seconds and further with warm air at 100° C. for 120 seconds to form an alignment layer, and a TAC film with the alignment layer was obtained.

A film thickness thereof was 1.0 μm.

(Coating Liquid 1 for Forming Alignment Layer)

| | | |
|---|---|---|
| The following modified polyvinyl alcohol | 3.80 | parts by mass |
| Initiator Irg2959 | 0.20 | parts by mass |
| Water | 70 | parts by mass |
| Methanol | 30 | parts by mass |

Modified polyvinyl alcohol

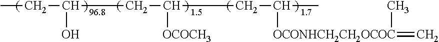

<Formation of Light Absorption Anisotropic Layer P1>

The following composition P7 for forming a light absorption anisotropic layer was continuously applied onto the obtained alignment layer PA1 with a wire bar to form a coating layer P7.

Next, the coating layer P7 was heated at 140° C. for 30 seconds, and the coating layer P7 was cooled to room temperature (23° C.).

Subsequently, the coating layer was heated at 90° C. for 60 seconds and cooled again to room temperature.

Thereafter, the coating layer was irradiated with light for 2 seconds under an irradiation condition of an illuminance of 200 mW/cm², using a LED lamp (center wavelength of 365 nm) to manufacture a light absorption anisotropic layer P7 on the alignment layer 1.

A film thickness and an alignment degree thereof were 2.1 μm and 0.96, respectively. A molar content of the radically polymerizable group is 1.16 mmol/g.

This layer was designated as the laminate 10B.

Composition P7 for forming light absorption anisotropic layer

| The dichroic substance D-1 | 0.40 | parts by mass |
|---|---|---|
| The dichroic substance D-4 | 0.15 | parts by mass |
| The dichroic substance D-5 | 0.63 | parts by mass |
| The high-molecular-weight liquid crystalline compound P-2 | 2.15 | parts by mass |
| The low-molecular-weight liquid crystalline compound M-1 | 1.36 | parts by mass |
| Polymerization initiator | | |
| IRGACURE OXE-02 (manufactured by BASF) | 0.140 | parts by mass |
| The following compound E-1 | 0.060 | parts by mass |
| The following compound E-2 | 0.060 | parts by mass |
| The following surfactant F-2 | 0.010 | parts by mass |
| The following surfactant F-3 | 0.015 | parts by mass |
| Cyclopentarione | 46.00 | parts by mass |
| Tetrahydrofuran | 46.00 | parts by mass |
| Benzyl alcohol | 3.00 | parts by mass |

Compound E-1 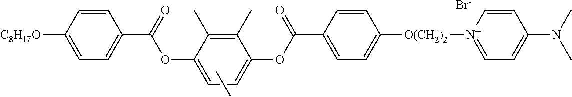
Compound E-2 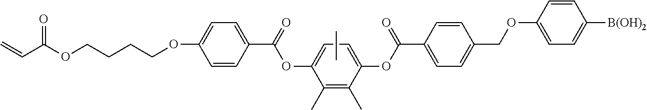
Surfactant F-2 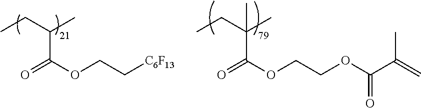
Surfactant F-3

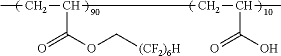

<Creation of Laminate 10>

TECHNOLLOY S001G (methacrylic resin 50 μm thickness, tan δ peak temperature of 128° C., available from Sumika Acryl Co., Ltd.) as the resin substrate S1 was bonded onto a surface of the light absorption anisotropic layer of the laminate 10B. Thereafter, only the cellulose acylate film 2 was peeled to create an absorption-type polarizing film in which the resin substrate/the adhesive layer/the light absorption anisotropic layer/the alignment layer were arranged in this order. A thickness of the UV adhesive layer was 2 μm.

Biaxial stretching evaluation in the same manner as for the laminates 1 to 9 was performed, and the effect of the present invention was confirmed.

### Creation Example 11

<Creation of Acrylate-Based UV Adhesive>

The following acrylate-based UV adhesive composition was prepared.

Acrylate-based UV adhesive composition

| | |
|---|---|
| ARONIX M220 (manufactured by Toagosei Co., Ltd.) | 18 parts by mass |
| 4-Hydroxybutyl acrylate (manufactured by | 40 parts by mass |
| Tokyo Chemical Industry Co., Ltd.) | |
| 2-Hydroxyethyl acrylate (manufactured by | 40 parts by mass |
| Tokyo Chemical Industry Co., Ltd.) | |
| IRGACURE 907 (manufactured by BASF) | 2 parts by mass |

<Creation of Laminate 11>

A resin substrate was affixed to a surface of the light absorption anisotropic layer of the laminate 1B in the same manner as in Creation Example 1, except that TECHNOLLOY S000 (methacrylic resin 75 μm thickness, tan δ peak temperature of 120° C., Sumika Acryl Co., Ltd.) was used as a resin substrate, using the acrylate-based UV adhesive. Thereafter, only the cellulose acylate film 1 was peeled to create a laminate 11 in which the resin substrate/the adhesive layer/the light absorption anisotropic layer/the alignment layer were arranged in this order.

A thickness of the UV adhesive layer was 2 μm. In addition, in the laminate 11, the light absorption anisotropic layer and the resin substrate were adhered very strongly by using an acrylate-based UV agent, and upon peeling the cellulose acylate film 1, the light absorption anisotropic layer could be easily peeled without being torn or peeled from the resin substrate.

<Molding into Lens Shape>

The laminate 11 was cut into 200 mm×300 mm, and subjected to vacuum molding by the method described in JP2012-116094A, using a convex lens having a diameter of 50 mm and a thickness of 10 mm as a mold. The molding temperature was 110° C.

It was confirmed that a change in the degree of polarization before and after molding was less than 0.5% even in a place where the change was the largest, and a decrease in the degree of polarization was greatly suppressed very well.

### EXPLANATION OF REFERENCES

100, 200: laminate

300: optical device or display device having curved surface

1: resin substrate

2: alignment layer

3: optical absorption layer

4: adhesive layer

10: head-mounted display

12: housing

20: optical system

40: display system

46: eye

48: direction

100: linear polarizer A (laminate of the embodiment of the present invention)

101: first ¼ wavelength plate

200: reflection linear polarizer

201: first ¼ wavelength plate

300: half mirror

399: second λ/4 plate

400: linear polarizer B

500: image display panel

600: reflection circular polarizer

What is claimed is:

1. A laminate comprising at least:
a resin substrate; and
a light absorption anisotropic layer,
wherein a tan δ peak temperature of the resin substrate is 170° C. or lower,
the light absorption anisotropic layer includes a liquid crystalline compound and a dichroic substance, and
an alignment degree of the dichroic substance is 0.95 or more.

2. The laminate according to claim 1,
wherein the tan δ peak temperature of the resin substrate is 130° C. or lower.

3. The laminate according to claim 1,
wherein a storage elastic modulus of the resin substrate at the tan δ peak temperature is 100 kPa or less.

4. The laminate according to claim 1,
wherein the resin substrate, an adhesive layer, and the light absorption anisotropic layer are arranged in this order.

5. The laminate according to claim 4,
wherein the adhesive layer is an ultraviolet curable adhesive layer.

6. The laminate according to claim 5,
wherein the adhesive layer is an adhesive layer including at least a (meth)acrylate compound.

7. The laminate according to claim 1, further comprising an alignment layer.

8. The laminate according to claim 7,
wherein the alignment layer is a layer formed from a composition containing a radically polymerizable compound.

9. The laminate according to claim 1,
wherein the resin substrate, an adhesive layer, the light absorption anisotropic layer, and an alignment layer are arranged in this order.

10. The laminate according to claim 9,
wherein the adhesive layer is an ultraviolet curable adhesive layer.

11. The laminate according to claim 10,
wherein the adhesive layer is an adhesive layer including at least a (meth)acrylate compound.

12. The laminate according to claim 1,
wherein the light absorption anisotropic layer is formed from a composition having a high-molecular-weight liquid crystalline compound.

13. The laminate according to claim 1,
wherein a molar content of a radically polymerizable group is 0.6 mmol/g or more with respect to a solid content weight of a composition forming the light absorption anisotropic layer.

14. The laminate according to claim 1,
wherein the laminate has a curved surface.

15. An optical device having a curved surface,
wherein the laminate according to claim 14 is arranged along the curved surface.

16. A display device comprising a plurality of members having a curved surface,
wherein the laminate according to claim 14 is arranged along a further visible side of a curved surface of a member present on the most visible side among the members having the curved surface.

17. The laminate according to claim 2,
wherein a storage elastic modulus of the resin substrate at the tan δ peak temperature is 100 kPa or less.

18. The laminate according to claim 2,
wherein the resin substrate, an adhesive layer, and the light absorption anisotropic layer are arranged in this order.

19. The laminate according to claim 18,
wherein the adhesive layer is an ultraviolet curable adhesive layer.

20. The laminate according to claim 19,
wherein the adhesive layer is an adhesive layer including at least a (meth)acrylate compound.
